(19) United States
(12) Patent Application Publication
(10) Pub. No.: US 2007/0115738 A1
(43) Pub. Date: May 24, 2007

(54) Failure management method for a storage system

(75) Inventors: Hironori Emaru, Yokohama (JP); Masahide Sato, Noda (JP); Wataru Okada, Odawara (JP); Hiroshi Wake, Yokohama (JP)

Correspondence Address: Stanley P. Fisher;Reed Smith LLP, Suite 1400, 3110 Fairview Park Drive, Falls Church, VA, 22042-4503, US

(73) Assignee: Hitachi, Ltd.

(21) Appl. No.: 11/334,625

(22) Filed: Jan. 19, 2006

(30) Foreign Application Priority Data
Nov. 21, 2005 (JP) 2005-335614

(51) Int. Cl. G11C 7/00

(52) U.S. Cl. 365/203

(57) ABSTRACT

Provided is a method of performing backup and recovery of data by using journaling, and performing management upon occurrence of a failure. The method includes: a first step of setting a recovery point indicative of the given time; a second step of creating an information of correspondence between the snapshot and the journal data which is required to restore data at the set recovery point time; a third step of detecting the occurrence of failure of the disk drive; and a fourth step of detecting the recovery point at which data cannot be restored due to the failure of the disk drive.

### CLAIM OF PRIORITY

The present application claims priority from Japanese application P2005-335614 filed on Nov. 21, 2005, the content of which is hereby incorporated by reference into this application.

### BACKGROUND

This invention relates to a storage system, and more particularly to backup and recovery of data by using journaling, and a management method used upon occurrence of a failure.

Up to now, in general, in a storage system that stores information resource therein, backup is acquired in order to recover data loss attributable to a failure of a hardware, viral induced data destruction, mishandling by a user, etc.

As one of means for recovering data, there has been proposed a backup and recovery technique using journaling. The journaling is directed to a backup and restoring technique that is generally employed in the storage system. More specifically, data image is acquired from data to be backed up which is stored in the storage system. Then, updated data is stored as a journal every time data is updated by a request from a host computer. It is possible that the storage system recovers the data image of data volume at a certain designated time point.

The data image of data volume at the certain designated time point is generally called “snapshot”. Also, in order to realize the above-mentioned journaling, some data volumes are generally operated together. The minimum unit of the operation is generally called “journal group”. In the storage system, when the recovery is required, the journal is applied to the snapshot, thereby making it possible to recover data at an arbitrary time point.

The following techniques of this type have been known. A snapshot at a specific time point of a certain journal group is acquired, and subsequent write data with respect to the journal group is stored as the journal. Also, when the recovery is necessary due to the occurrence of a failure, the journals are applied to the acquired snapshot in the written order, thereby making it possible to recover data at a specific time point (refer to US 2005/0015416).

A specific time point that is designated by a user at the time of recovering data is called “recovery point”.

### SUMMARY

In the case of using the above-mentioned backup operation using the journaling, the data loss may occur in a volume in which the snapshots are stored or a volume in which the journals are stored, for example, due to the failure of a physical disk.

In the case where the above failure occurs, the user stops the backup operation and removes a factor of the failure, and thereafter needs to restart the operation. This is because the extent of an impact due to the invalidity of a recovery point is not found due to the failure of data.

In order to recover data at the recovery point designated by the user, it is necessary to apply all of the journals including a journal corresponding to the recovery point that has been designated by the user to the snapshots that have been acquired at a time point nearest to the designated recovery point in the written order. Accordingly, when a failure occurs in a volume in which a certain journal is stored, all of the recovery points that are recovered by using the journal are lost. However, other recovery points are valid.

This invention has been made in view of the above problems, and it is therefore an object of the invention to provide an operating method that can continue the backup operation by recovery points other than recovery points that have been invalidated due to the data loss without stopping the backup operation even in the case where the failure of data occurs in the volume in which the snapshots or the journals are stored.

According to an embodiment of this invention, there is provided an operating method including: a first step of setting a recovery point indicative of a given time; a second step of creating an information of correspondence between snapshots and journal data which is required to restore data at the set recovery time point; a third step of detecting the occurrence of a failure of a disk drive; and a fourth step of detecting a recovery point at which the recovery of data is disabled due to the failure of the disk drive.

According to this invention, in the case where a failure occurs in the volume in which the snapshots or the journals are stored, and the data loss occurs, since recovery points that have been invalidated due to the data loss can be found, the backup operation can be continued by using recovery points other than the invalidated recovery points without stopping the backup operation.

### BRIEF DESCRIPTION OF THE DRAWINGS

FIG. 1 is a structural block diagram showing a computer system according to a first embodiment of this invention.

FIG. 2 is an explanatory diagram showing an example of a volume failure table according to the first embodiment of this invention.

FIG. 3 is an explanatory diagram showing an example of a journal group table according to the first embodiment of the present invention.

FIG. 4 is an explanatory diagram showing an example of a journal volume table according to the first embodiment of this invention.

FIG. 5 is an explanatory diagram showing an example of a snapshot table according to the first embodiment of this invention.

FIG. 6 is an explanatory diagram showing a structure of a journal volume according to the first embodiment of this invention.

FIG. 7 is an explanatory diagram showing an example of a recovery point table according to the first embodiment of this invention.

FIG. 8 is an explanatory diagram showing an example of an application table according to the first embodiment of this invention.

FIG. 9 is an explanatory diagram showing an example of a status management table according to the first embodiment of this invention.

FIG. 10 is an explanatory diagram showing an application information setting screen to be backed up according to the first embodiment of this invention.

FIG. 11 is a flowchart for setting an application to be backed up according to the first embodiment of this invention.

FIG. 12 is a flowchart showing a recovery point creating process according to the first embodiment of this invention.

FIG. 13 is a flowchart showing a volume failure event receiving process according to the first embodiment of this invention.

FIG. 14 is an explanatory diagram showing an example of GUI of notification to a user according to the first embodiment of this invention.

FIG. 15 is an explanatory diagram showing another example of GUI of notification to the user according to the first embodiment of this invention.

FIG. 16 shows a physical view GUI according to the first embodiment of this invention.

FIG. 17 is an explanatory diagram showing an example of a status management table according to a second embodiment of this invention.

FIG. 18 is an explanatory diagram showing a structure of a journal volume according to a third embodiment of this invention.

FIG. 19 is an explanatory diagram showing an example of a journal volume table according to the third embodiment of this invention.

FIG. 20 is an explanatory diagram showing an example of a before JNL creation notification table according to the third embodiment of this invention.

FIG. 21A is an explanatory diagram showing an example of a status management table according to the third embodiment of this invention.

FIG. 21B is an explanatory diagram showing an example of a status management table according to the third embodiment of this invention.

FIG. 22 is a flowchart showing a recovery point creating process according to the third embodiment of this embodiment.

### DETAILED DESCRIPTION OF THE PREFERRED EMBODIMENTS

Hereinafter, a description will be given of embodiments of this invention with reference to the accompanying drawings, by which this invention is not limited.

### First Embodiment

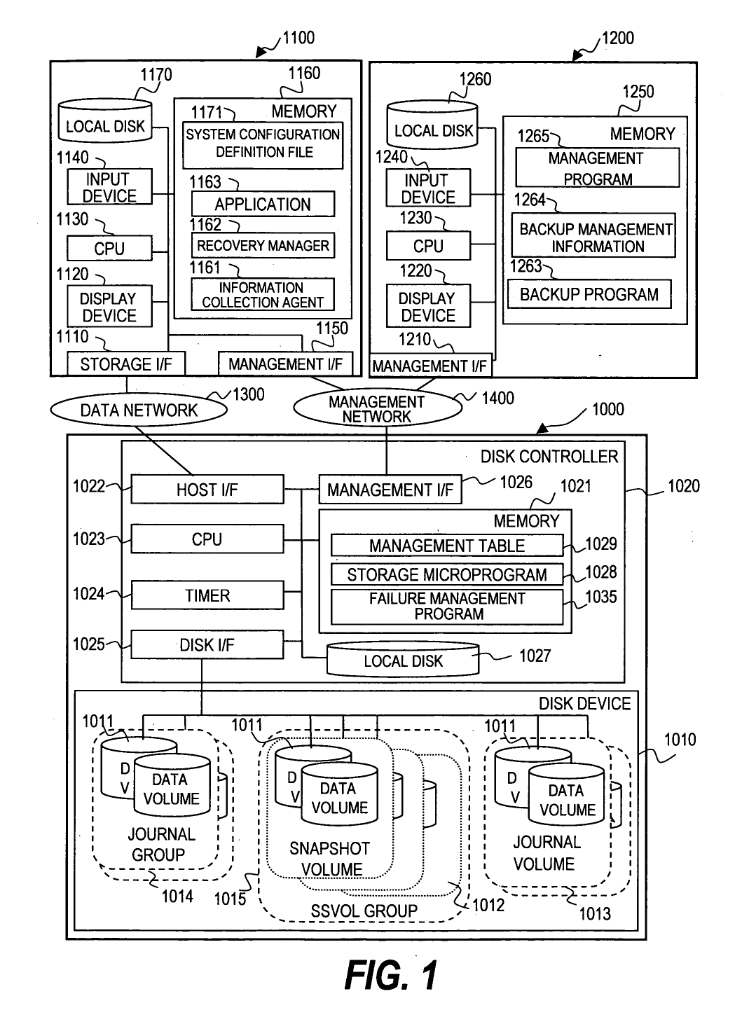

FIG. 1 is a structural block diagram showing a computer system according to a first embodiment of this invention.

The computer system according to this embodiment includes a storage system 1000, a host computer 1100, and a management computer 1200.

The storage system 1000 and the host computer 1100 are connected to each other via a data network 1300. The data network 1300 to be used is a SAN (storage area network). The data network 1300 is not limited to this structure, but may be formed of an IP network or other data communication networks.

The storage system 1000 and the host computer 1100 are connected to the management computer 1200 via a management network 1400. The management network 1400 to be used is an IP network. The management network 1400 may be the storage area network or other data communication networks. Also, the data network 1300 and the management network 1400 may be physically or logically the same network. Further, the management computer 1200 and the host computer 1100 may be realized on the same computer.

For convenience of description, FIG. 1 shows one storage system 1000, one host computer 1100, and one management computer 1200. However, the numbers of those elements are not limited.

The storage system 1000 includes a disk device 1010 that stores data therein, and a disk controller 1020 that controls the input/output of data with respect to the disk device 1010.

The disk device 1010 includes plural data volumes 1011 that are data storage areas. The data volume 1011 may be formed of a RAID structure. Also, the data volume 1011 may be formed of a physical disk device, and in this embodiment, the type of the data volume 1011 is not restricted.

The data volume 1011 configures a journal group 1014, an SSVOL group 1015, and a journal volume 1013.

The journal group 1014 is an area in which data including at least one data volume 1011 is stored. The data volume 1011 of the journal group 1014 stores write data from the host computer 1100 therein.

The journal group 1041 is a logical storage area that collects up some data volumes 1011 in order to realize the journaling. Also, the journal group 1014 is a set of the operation volumes that are plural logical storage areas, and may supply the operation volumes in order to store data of application of the host computer. In this case, the operation volume is made up of one or more data volumes.

In order to realize the snapshot and recovery using the journal created by an access from the host computer 1100, it is necessary to operate some data volumes 1011 together. The minimum unit of the operation is called “journal group”. Referring to FIG. 1, two data volumes are indicated in the journal group 1014, but the number of data volumes is not limited. Similarly, the number of journal groups 1014 is not limited.

The snapshot volume group (SSVOL group) 1015 is an area that stores a replication image of the journal group 1014 therein. The SSVOL group 1015 includes a snapshot volume 1012 which is an area that stores the replication image (called “snapshot”) of the journal group 1014 at a certain time point therein. The snapshot volume 1012 is made up of data volumes 1011.

The snapshot is a data image of the journal group 1014 at a certain designated time point. Snapshot volumes 1012 of plural generations can be retained with respect to one journal group 1014 according to a request from an administrator. For example, three snapshots at specific times, more specifically, a time point of 12:00, a time point of 18:00, and a time point of 24:00 can be stored in the SSVOL group 1015 as individual snapshot volumes 1012 with respect to a certain journal group 1014, respectively. In FIG. 1, two data volumes are indicated in the snapshot volume 1012, but the number of snapshot volumes 1012 is not limited.

In the replication image that is stored in the snapshot volume 1012, various configurations can be used according to a request to the system, implementation, or the like. For example, backup images corresponding to all of the data volumes 1011 of the journal group 1014 may be stored in the snapshot volume 1012. Alternatively, logical data images such as differential backup corresponding to the respective data volumes 1011 may be stored in the snapshot volume 1012.

The journal volume 1013 is a storage area in which the journals in the journal group 1014 are stored. The journal volume 1013 includes one or more data volumes 1011. The journals are stored in the data volumes 1011. In FIG. 1, two journal volumes 1013 are indicated in correspondence with the two journal groups 1014, respectively, but the number of journal volumes 1013 is not limited.

The disk controller 1020 processes writing in the data volume 1011 in the case where a write request is given to the data volume 1011 included in the journal group 1014 from the host computer 1100. In this situation, a journal that is given an appropriate sequence number corresponding to the write request is created and then stored in the journal volume 1013 associated with the journal group 1014. Also, the snapshot volume 1012 is created from the journal group 1014 and the journal volume 1013 according to a request from the host computer 1100.

The disk controller 1020 includes a host I/F 1022, a management I/F 1026, a disk I/F 1025, a main memory 1021, a CPU 1023, a timer 1024, and a local disk 1027.

The memory 1021 is a device where various programs are loaded, management data, and the like therein. The memory 1021 is formed of, for example, a RAM.

The host I/F 1022 is an interface that is connected to the data network 1300. The host I/F 1022 transmits and receives data and control commands with respect to the host computer 1100.

The CPU 1023 loads the program stored in the local disk 1027 into the memory 1021 and executes the program to execute a process that is defined in the program.

The timer 1024 has a function of supplying a present time. The timer 1024 has the present time to which a storage microprogram 1028 refers, for example, when creating a journal or acquiring a snapshot in the disk controller 1020.

The disk I/F 1025 is an interface that is connected to the disk device 1010. The disk I/F 1025 transmits or receives data and control commands with respect to the disk device 1010.

The management I/F 1026 is an interface that is connected to the management network 1400. The management I/F 1026 transmits and receives data and control commands with respect to the host computer 1100 and the management computer 1200.

The local disk 1027 is a storage device such as a hard disk. The local disk 1027 stores a storage microprogram 1028, a failure management program 1035, and the like therein.

The storage microprogram 1028 controls the functions of journaling such as acquisition of the snapshots, creation of the journals, recovery using the journal, or release of the journals. The storage microprogram 1028 refers to and updates the information on the management table 1029 when conducting the control. Also, the storage microprogram 1028 executes various controls such as control of input/output of data with respect to the disk device 1010, the setting of control information within a storage system, and the supply of control information, on the basis of a request from the management computer 1200 or the host computer 1100.

The management table 1029 is information that is managed by the storage microprogram 1028. The management table 1029 has information related to the journal group 1014, the journal volumes 1013 and the SSVOL group 1015, and information related to the failure of the disk device 1010, which is stored therein.

The failure management program 1035 monitors the failure of the disk device 1010. Upon detecting the failure of the data volume 1011 in the disk device 1010, the failure management program 1035 creates a volume failure table 2000. Then, the failure management program 1035 notifies the management computer 1200 of the volume failure table 2000 as a volume failure event.

The storage microprogram 1028 and the failure management program 1035 may be stored not in the local disk 1027 but in an arbitrary volume 1011 within the disk device 1010. Also, a storage device such as a flash memory is disposed within the disk controller 1020, and the storage microprogram 1028 may be stored in the storage system.

The host computer 1100 includes a storage I/F 1110, a display device 1120, a CPU 1130, an input device 1140, a management I/F 1150, a memory 1160, and a local disk 1170.

The storage I/F 1110 is an interface that is connected to the data network 1300. The storage I/F 1110 transmits and receives data and control commands with respect to the storage system 1000.

The display device 1120 is made up of a CRT display device and the like, and displays the contents of a process that is executed by the host computer 1100.

The CPU 1130 reads the program stored in the local disk 1170 in the memory 1160 and executes the program to execute a process that is defined in the program.

The input device 1140 is made up of an input device such as a keyboard or a mouse, and inputs an instruction and information to the host computer 1100 by the operation of the administrator.

The management I/F 1150 is an interface that is connected to the management network 1400. The management I/F 1150 transmits and receives data and control commands with respect to the storage system 1000 and the management computer 1200.

The memory 1160 is a storage device where various programs are loaded, management data, and the like therein. The memory 1160 is formed of, for example, a RAM.

The local disk 1170 is a storage device such as a hard disk. The local disk 1170 stores a system configuration definition file 1171, an application 1163, a recovery manager 1162, an information collection agent 1161, and the like.

A system configuration definition file 1171 stores the configuration definition of the system including which data volume 1011 is used by an application 1163 and which journal group 1014 the data volume 1011 belongs to. The system configuration definition file 1171 is set by the administrator at the time of configuring the system. For example, /etc/fstab file used at the time of configuring a Linux operating system corresponds to the system configuration definition file.

The application 1163, a recovery manager 1162, and an information collection agent 1161 are programs which are read in the memory 1160 by the CPU 1130, and functions that are defined in the respective programs are executed by the CPU 1130.

The application 1163 reads or writes data from or to the data volume 1011. The application 1163 is, for example, a DBMS or a file system. In the host computer 1100, plural applications 1163 may be executed at the same time.

The recovery manager 1162 requests the acquisition of snapshots with respect to the storage microprogram 1028, the recovery of data at a specific time point with respect to the storage microprogram 1028, and the freezing of the application 1163. Also, the recovery manager 1162 sets backup using the journaling to the management table 1029 of the storage system 1000 on the data network 1300. Those functions are supplied by a command line interface (hereinafter referred to as “CLI”) to be executed by the administrator or other programs.

The information collection agent 1161 is a program that collects the system configuration information of the host computer 1100. The information collection agent 1161 specifies the storage system 1000 to which the journal group 1014 that is used by the application 1163 belongs and the journal group 1014, from the system configuration definition file 1171 that is stored in the local disk 1170 according to a request from the management computer 1200. Then, the information collection agent 1161 transmits the identifier of the specified storage system 1000 and the identifier 1014 of the journal group to the management computer 1200.

The management computer 1200 includes a management I/F 1210, a display device 1220, a CPU 1230, an input device 1240, a memory 1250, and a local disk 1260.

The management I/F 1210 is an interface that is connected to the management network 1400. The management I/F 1210 transmits and receives data and control commands with respect to the storage system 1000 and the host computer 1100.

The display device 1220 is made up of a CRT display device and the like, and displays the contents of a process that is executed by the management computer 1200.

The CPU 1230 loads the program stored in the local disk 1260 into the memory 1250 and executes the program to execute a process that is defined in the program.

The input device 1240 is made up of an input device such as a keyboard or a mouse, and inputs an instruction and information to the management computer 1200 by the operation of the administrator.

The memory 1250 is a storage device where various programs are loaded, management data, and the like therein. The memory 1250 is formed of, for example, a Random Access Memory (RAM).

The local disk 1260 is a storage device such as a hard disk. The local disk 1260 stores a management program 1265 and a backup program 1263 therein.

The backup management information 1264 is a table that stores information for conducting the backup management, the snapshots, and the recovery points therein. The backup management information 1264 is created in the memory 1250 by the management program 1265.

The management program 1265 sets the management information on the overall computer system of this embodiment. The management program 1265 has a graphical user interface (GUI), and receives a setting instruction from the user. Also, the management program 1265 receives information from the backup program 1263 and sets backup management information 1264.

The backup program 1263 creates a recovery point in the disk device 1010 of the storage system 1000, and also controls a function related to the restoration due to the snapshot.

Subsequently, a description will be given of a volume failure table 2000.

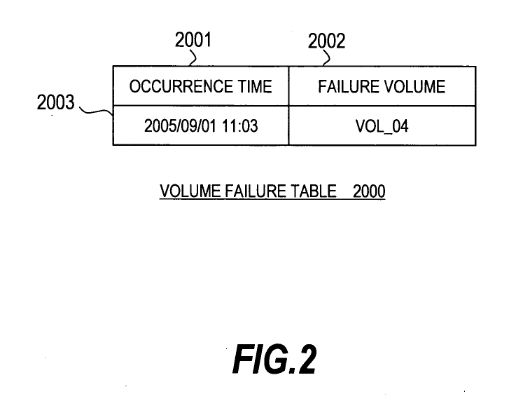

FIG. 2 is an explanatory diagram showing an example of the volume failure table 2000.

The volume failure table 2000 is information that is created by the failure management program 1035 and transmitted to the management computer 1200. The volume failure table 2000 includes an entry 2003 with an occurrence time field 2001 and a failure volume ID field 2002.

The occurrence time field 2001 stores a time at which a failure occurs therein. The failure volume ID field 2002 stores the identifier (volume ID) of the data volume 1011 in which a failure occurs therein.

In the storage system 1000, the failure management program 1035 monitors the failure of the disk device 1010. Upon detecting the failure of the volume within the disk device 1010, the failure management program 1035 acquires a time at that time point from the timer 1024 and sets the time to the occurrence time field 2001 of the entry 2003. Then, the failure management program 1035 acquires the volume ID of the data volume in which the failure occurs, and sets the volume ID to the failure volume ID field 2002.

As the volume failures within the disk device, there are various failures such as the physical failure of the disk device, the logical failure of the logical volume, for example, a case in which an abnormality occurs in the configuration information, and the read and write of data is not normal.

Then, the failure management program 1035 notifies the management program 1265 of the management computer 1200 of the volume failure table 2000 as the volume failure event. As the notifying method, an SNMP (simple network management protocol) trap is used, but other method may be applied.

Subsequently, a description will be given of the management table 1029 that is stored in the storage system 1000.

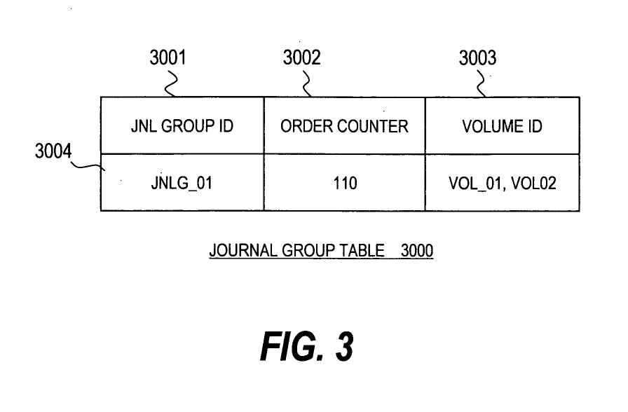

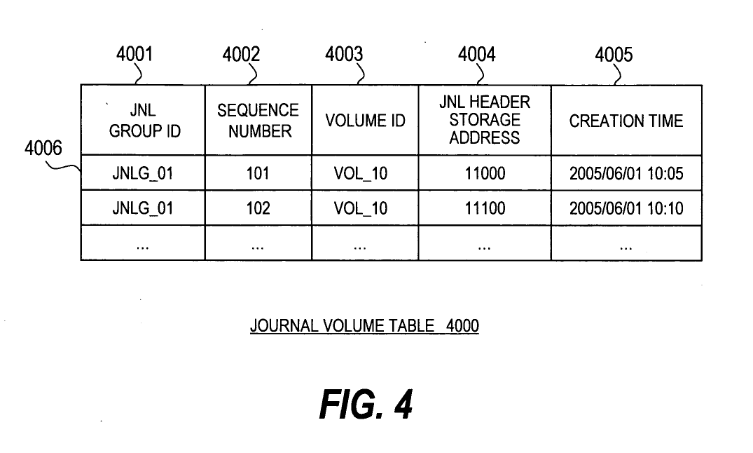

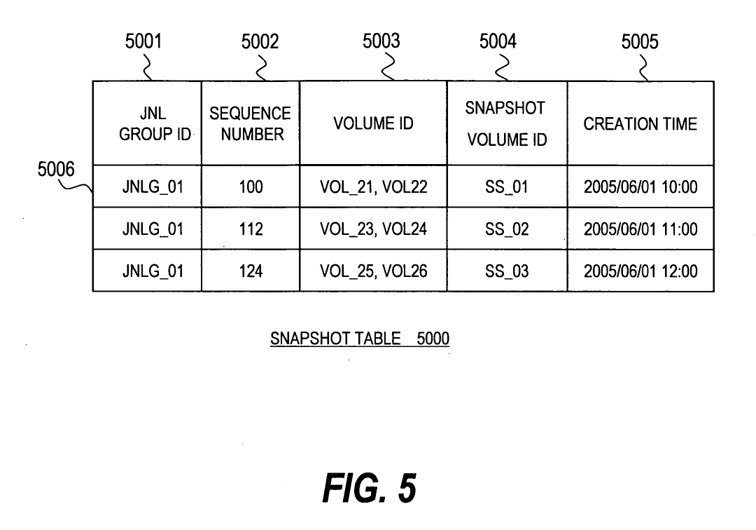

The management table 1029 is a table group including a journal group table 3000 shown in FIG. 3, a journal volume table 4000 shown in FIG. 4, and a snapshot table 5000 shown in FIG. 5.

FIG. 3 is an explanatory diagram showing an example of the journal group table 3000 included in the management table 1029.

The journal group table 3000 stores the identifier of the journal group therein. The journal group table 3000 includes an entry 3004 having a JNL group ID field 3001, an order counter field 3002, and a volume ID field 3003.

The JNL group ID field 3001 stores the identifier (JNL group ID) of the journal group 1014 therein. The order counter field 3002 stores a number for managing a journal and snapshot creating order therein. The volume ID field 3003 stores the volume ID of the data volume 1011 included in the journal group 1014 therein.

The JNL group ID field 3001 and the volume ID field 3003 are set by the administrator by using the CLI that is supplied from the recovery manager 1162 of the host computer 1100 at the time of configuring the computer system. With this operation, it is managed which data volume 1011 the journal group 1014 is configured by.

A value that is stored in the order counter field 3002 is incremented by 1 by the storage microprogram 1028 every time the storage microprogram 1028 creates the journal with respect to the write from the host computer 1100. The storage microprogram 1028 copies the added value to a sequence number field 4002 of the journal volume table 4000 (refer to FIG. 4).

Also, a value that is stored in the order counter field 3002 is copied to a sequence number 5002 of the snapshot table 5000 (refer to FIG. 5) by the storage microprogram 1028 every time the storage microprogram 1028 acquires the snapshot. As a result, an order relationship between the snapshots and the respective journals are recorded, and a journal to be applied to the snapshot at the time of recovery can be specified. More specifically, in the case where the journal is applied to the specific snapshot to conduct recovery, the storage microprogram 1028 applies the journals having the sequence numbers that are equal to or lower than the sequence number of a journal having the designated recovery point among the journals of the sequence numbers that are larger than the sequence number of the specific snapshot according to the sequence numbers.

FIG. 4 is an explanatory diagram showing an example of the journal volume table 4000 included in the management table 1029.

The journal volume table 4000 is a table for managing the journal data that has been acquired with respect to the journal group 1014.

The journal volume table 4000 includes an entry 4006 with a JNL group ID field 4001, a sequence number field 4002, a volume ID field 4003, a JNL header storage address field 4004, and a creation time field 4005.

The storage microprogram 1028 creates the journal and stores the journal in the data volume 1011 of the journal volume 1013 every time writing is conducted with respect to the journal group 1014 from the host computer 1100. In this situation, the storage microprogram 1028 creates the entry 4006 corresponding to the created journal data, and adds the entry 4006 to the journal group table 4000.

The JNL group ID field 4001 stores a JNL group ID that is the identifier of the journal group 1014 in which writing is conducted by the host computer 1100 therein. The storage microprogram 1028 acquires the volume ID of the data volume 1011 in which writing has been conducted, and acquires the JNL group ID from the volume ID with reference to the journal group table 3000. Then, the storage microprogram 1028 stores the acquired JNL group ID in the JNL group ID field 4001.

The sequence number field 4002 stores the sequence number therein. The sequence number is used in order to determine which journal should be applied to which snapshot at the time of recovery. The storage microprogram 1028 sets the sequence number in the order counter 3003 of the journal group table 3000 when creating the journal with respect to the writing from the host computer 1100. Then, the storage microprogram 1028 acquires the sequence number and sets the sequence number to the sequence number field 4002.

The volume ID field 4003 stores a volume ID that is the identifier of the data volume 1011 of the journal volume 1013 in which the journal is stored therein.

The JNL header storage address field 4004 stores therein an address within the data volume in which a journal header is stored.

In writing the journal in the journal volume 1013, the storage microprogram 1028 acquires the volume ID that is the identifier of the journal write area and the JNL header storage address, and stores those values in the volume ID field 4003 and the JNL header storage address field 4004.

The creation time field 4005 stores a time at which a write request from the host computer 1100 reaches the storage system 1000 therein. When the write request from the host computer 1100 reaches the storage system 1000, the storage microprogram 1028 acquires the time from the timer 1024 of the disk controller 1020, and stores the time in the creation time field 4005.

The creation time becomes a recovery point that is designated by the administrator at the time of recovery. A write issuance time included in the write request from the host computer 1100 may be set to the creation time. For example, under the mainframe environments, a main frame host has a timer and includes a time at which the write command is issued within the write request. For that reason, the time may be utilized as the creating time.

FIG. 5 is an explanatory diagram showing an example of the snapshot table 5000 included in the management table 1029.

The snapshot table 5000 is a table for managing the snapshot that has been acquired.

The snapshot table 5000 includes an entry 5006 with a JNL group ID field 5001, a sequence number field 5002, a volume ID field 5003, a snapshot volume ID field 5004, and a creation time field 5005.

The JNL group ID field 5001 stores a JNL group ID that is the identifier of the journal group 1014 to be acquired therein. The sequence number field 5002 stores a sequence number indicative of an order in which the snapshots have been acquired therein. The volume ID field 5003 stores therein a volume ID that is the identifier of the data volume 1011 of the snapshot volume 1012 in which the snapshots are stored. The snapshot volume ID field 5004 stores therein the snapshot volume ID that is the identifier of the snapshot volume in which the snapshots are stored. The creation time field 5005 stores the creation time.

The JNL group ID and the snapshot volume ID are associated with each other by means of the CLI that is supplied by the recovery manager 1162 by the administrator in the host computer 1100. For example, the administrator issues the following commands.
addSSVOL ?jgid JNLG_{—}01 ?ssvolid SS₁₃ 01

The above command is a request that associates the journal group 1014 whose journal group ID is “JNLG—01” with the snapshot volume 1012 whose snapshot volume ID is “SS—01 ”.

The above command allows “JNLG_01” to be stored in the JNL group ID field 5001, and allows “SS_01” to be stored in the snapshot volume ID field 5004. In the case of setting the snapshots of plural generations, the above command is executed by plural times.

The sequence number field 5002 copies the sequence number that has been stored in the order counter field 3003 of the journal group table 3000 to store the sequence number therein every time the storage microprogram 1028 acquires the snapshots.

The creation time field 5005 acquires a time at which the snapshot acquisition request from the recovery manager 1162 reaches the storage system 1000, from the timer 1024 by the storage microprogram 1028, and stores the time therein. As described above, the creation time field 5005 may set the request issuance time included in the snapshot acquisition request from the host computer 1100 to the creation time.

The above is a table group included in the management table 1029.

Subsequently, the structure of the journal volume 1013 will be described.

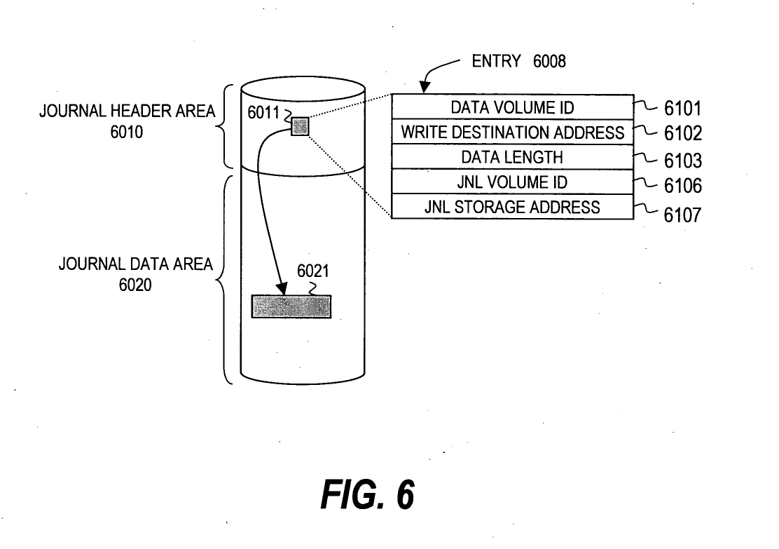

FIG. 6 is an explanatory diagram showing the structure of the journal volume 1013.

The journal volume 1013 is logically divided into a journal header area 6010 and ajournal data area 6020.

In the storage system 1000, when the journal is stored in the journal volume 1013, the storage microprogram 1028 divides the journal into a journal header 6011 and a journal data 6021. The journal header 6011 is stored in the journal header area 6010, and the journal data 6021 is stored in the journal data area 6020.

The journal data 6021 is data that is written in the data volume 1011, and the journal header 6011 is data that retains information related to the journal data 6021.

The journal header 6011 includes an entry 6008 with a data volume ID 6101, a write destination address 6102, a data length 6103, a JNL volume ID 6106, and a JNL storage address 6107.

The data volume ID 6101 stores the volume ID that is the identifier of the data volume 1011 to which the journal data is to be written at the time of applying the journal therein.. The write destination address 6102 stores the address to which the journal data is written at the time of applying the journal therein. The data length 6103 stores the length of write data therein. Those values are acquired by analyzing the write request from the host computer 1100, and are then set to the journal header 6011 by the storage microprogram 1028.

The JNL volume ID 6106 stores the volume ID that is the identifier of the volume that stores the journal data therein.

The JNL storage address 6107 stores therein the address at which the journal data within the volume is stored. Those values are set by the storage microprogram 1028 at the time of creating the journal. Also, in the case where the journal data is opened, the storage microprogram 1028 stores the “NULL” in the JNL volume ID 6106 and the JNL storage address 6107.

Subsequently, a description will be given of a recovery point table 7000.

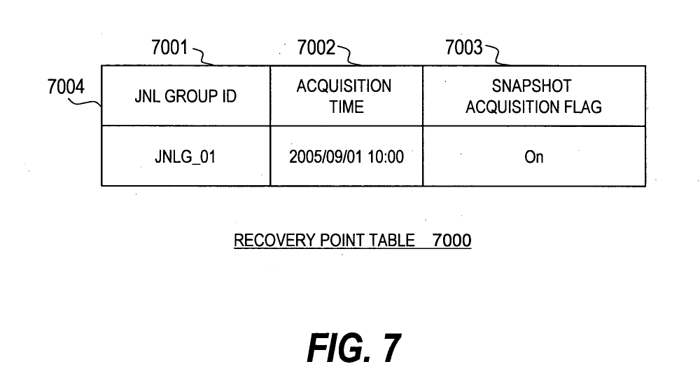

FIG. 7 is an explanatory diagram showing an example of the recovery point table 7000.

The recovery point table 7000 is created when the backup program 1263 acquires the recovery point. The backup program 1263 notifies the management program 1265 of the created recovery point table 7000 as a recovery point creation event.

The recovery point table 7000 includes an entry 7004 with a JNL group ID field 7001, an acquisition time field 7002, and a snapshot acquisition flag field 7003.

The JNL group ID field 7001 stores a JNL group ID that is the identifier of the journal group 1014 from which the recovery point is acquired therein.

The acquisition time field 7002 stores a time at which the recovery point has been acquired therein. This time is acquired from the timer 1024 of the storage system 1000. It is possible that the management computer 1200 has a timer, and a time is acquired from this timer.

An identifier indicating whether the snapshot has been acquired at a timing of the recovery point acquisition, or not, is stored in the snapshot flag field 7003. In the case where the snapshot has been acquired, “on” is stored. In the case where the snapshot has not been acquired, “off” is stored.

Subsequently, a description will be given of the backup management information that is stored in the management computer 1200.

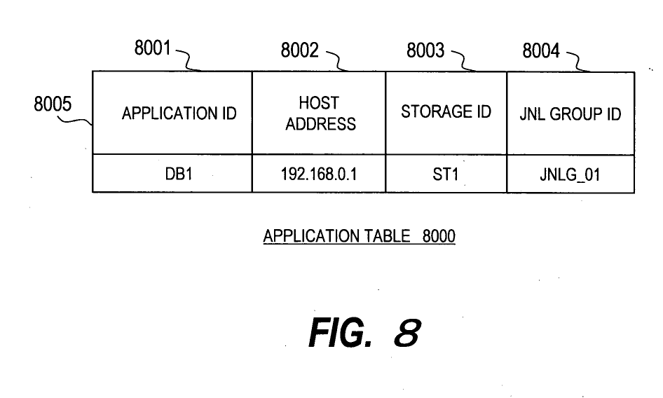

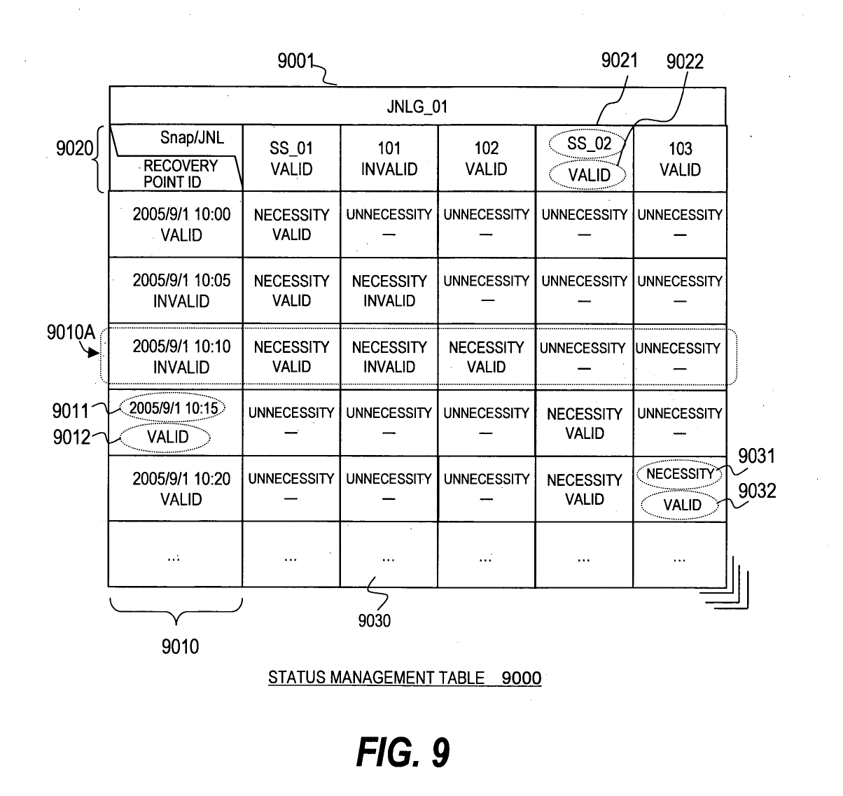

The backup management information 1264 is a table group including an application table 8000 shown in FIG. 8 and a status management table 9000 shown in FIG. 9.

FIG. 8 is an explanatory diagram showing an example of the application table 8000 included in the backup management information 1264.

The application table 8000 is a table in which information for managing the backup, which is managed by the backup program 1263, is stored.

The application table 8000 includes an entry 8005 with an application ID field 8001, a host address field 8002, a storage ID field 8003, and a JNL group ID field 8004.

The application ID field 8001 stores the identifier of the application 1163 that utilizes data of the journal group to be backed up therein.

The host address field 8002 stores the identifier of the host computer 1100 that executes the application 1163 on the network therein. An IP address etc. are stored in the identifier.

The storage Id field 8003 stores the identifier of the storage system 1000 to which the journal group used by the application 1163 belongs therein.

The JNL group ID field 8004 stores a JNL group ID that is the identifier of the journal group which is used by the application 1163 therein.

The application ID field 8001 and the host address field 8002 are set by the administrator through the GUI that is supplied by the management program 1265 of the management computer 1200.

The storage ID field 8003 and the JNL group ID field 8004 indicates the correspondence between an application and a journal group that is used by the application. In those storage ID field 8003 and JNL group ID field 8004, a value acquired by requesting the information collection agent 1161 by the management program 1265 is set. The storage ID field 8003 stores an ID for uniquely identifying the storage system such as a serial number therein.

FIG. 9 is an explanatory diagram showing an example of the status management table 9000 included in the backup management information 1264.

One status management table 9000 is generated with respect to one journal group. In the case where there exist plural journal groups, plural status management tables 9000 are created.

The status management table 9000 is a table that is made up of a target JNL group ID 9001, a recovery point header field 9001, and a Snap/JNL field 9020.

The subject JNL group ID 9001 stores a JNL group ID that indicates for which journal group the status management table 9000 is therein The recovery point header field 9010 stores the recovery point ID and its status therein.

The Snap/JNL header field 9020 stores an identifier and its status of the snapshot or journal which is required for recovering the respective recovery points therein.

Each of the recovery point headers that configure the recovery point header field 9010 includes a recovery point ID 9011 and a recovery point validity flag 9012. The recovery point ID 9011 stores a time at which the recovery point is acquired therein. The recovery point validity flag 9012 stores a flag that indicates whether the recovery point indicated by the recovery point ID is valid or invalid due to a failure therein. The recovery point validity flag 9012 sets “valid” or “invalid” from the status of the snapshot or journal by the management program 1265.

Each of the Snap/JNL headers that configure the Snap/JNL header fields 9020 includes an identifier 9021 and a data validity flag 9022. The identifier 9021 stores the snapshot volume ID that is stored in the snapshot table 5000 therein in the case where an object is a snapshot. Also, in the case where the object is a journal, the identifier 9021 stores the sequence number 4002 that is stored in the journal volume table 4000 therein. The data validity flag 9022 sets “validity” or “invalidity” from the status of the snapshot or journal by the management program 1265.

Each of cells that configure the table includes a necessity flag 9031 and a validity flag 9032.

The necessity flag 9031 is a flag that indicates which snapshot or journal is required in order to recover the recovery point that is indicated by the recovery point header on its row. The necessity flag 9031 has “necessity” stored at the recovery point by the management program 1265 therein in the case where the snapshot or journal indicated by the Snap/JNL header is necessary. If the snapshot or journal is not necessary, the necessity flag 9031 has “unnecessity” stored therein.

The validity flag 9032 indicates whether the snapshot or journal which corresponds to each of the cells is valid or invalid due to a failure. This flag is set only when a value “necessity” is set in the necessity flag. The flag is set with “validity” by the management program 1265 when the data validity flag of the corresponding Snap/JNL field is “valid”, and set with “invalidity” when the data validity flag is “invalid”.

A column 9010A will be described as an example with reference to FIG. 9.

A column including the recovery point header 9010A has information related to a recovery point “2005/9/1 10:10” stored in each of the cells. Each of the cells 9030 indicates which snapshot or journal is necessary in order to recover the recovery point “2005/9/1 10:10”. More specifically, the necessity flag 9031 is “necessity” when three of the snapshot “SS_01”, the journal “101”, and the journal “102” are indicated. In addition, because the validity flag 9022 of the journal “101” is set with “invalidity”, “invalidity” is also set in the validity flag 9032 of the corresponding cell. As a result, the recovery point “2005/9/1 10:10” is set as invalidity.

The administrator can be informed of the recovery point that is valid or invalid from the information of the management information table.

Subsequently, a description will be given of the operation of the first embodiment of this invention.

First, the operation of the management program 1265 of the management computer 1200 will be described.

The management program 1265 executes setting of an application to be backed up, update of the status management table 9000 at the time of creating the recovery point, and update of the status management table 9000 at the time of receiving the volume failure event.

First, the setting of an application to be backed up will be described.

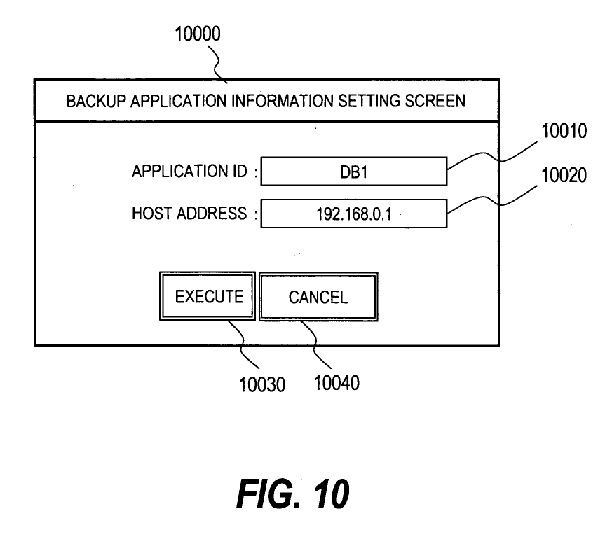

FIG. 10 is an explanatory diagram showing a backup application information setting screen 10000 which is a GUI supplied by the management program 1265.

The backup application information setting screen 10000 is displayed on a display device 1220 by requiring display of the management program 1265 through the CLI or the like by the administrator when setting the information of the application to be backed up.

The backup application information setting screen 10000 includes an application ID input field 10010, a host address input field 10020, an execution button 10030, and a cancel button 10040.

The application ID input field 10010 is a field for inputting an application ID that is an identifier of the application which is set to be backed up.

The host address input field 10020 is a field for inputting the identifier of the host computer 1100 that executes the application which is set to be backed up. The identifier uses an IP address. Alternatively, another identifier such as a host name may be used.

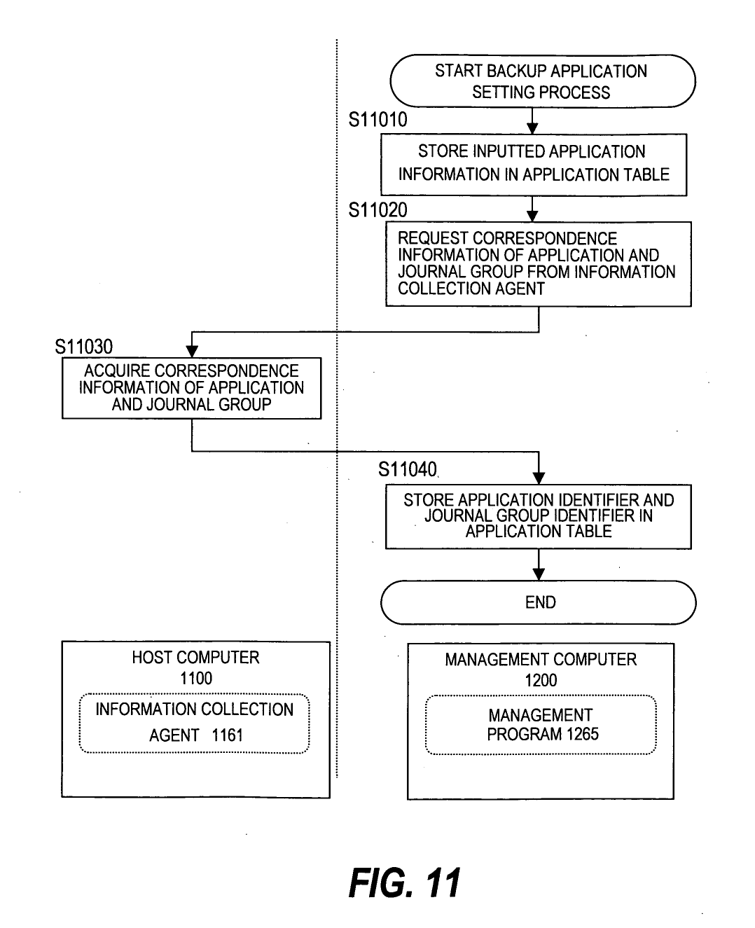

When the administrator depresses the execution button 10030 after inputting information necessary for the application ID input field 10010 and the host address input field 10020, the processing of the management program 1265 which will be described with reference to FIG. 11 is executed. In the case where the administrator depresses the cancel button 10040, the management program 1265 is finished with doing nothing.

FIG. 11 is a flowchart for setting an application to be backed up.

This flowchart is executed by the management program 1265 when the execution button 10030 is depressed on the screen shown in FIG. 10.

First, the management program 1265 stores a value set in the application ID input field 1010 in the application ID field 8001 of the application table 8000. Then, the management program 1265 stores a value set in the host address input field 10020 in the host address field 8002 of the application table 8000 (step S11010).

Subsequently, the management program 1265 connects to the host computer 1100 corresponding to the identifier that is stored in the host address field 8002, transmits the application ID to the information collection agent 1161, and requests an acquisition of the correspondence of the application and the journal (step S11020).

Upon receiving a request from the management program 1265, the information collection agent 1161 acquires the data volume 1011 that is used by the received application ID with reference to the system configuration definition file 1171. Then, the information collection agent 1161 acquires the identifier of the journal group 1014 to which the acquired data volume 1011 belongs and the identifier of the storage system to which the journal group 1014 belongs. The information collection agent 1161 responds to the management program 1265 of the management computer 1200 with the identifier of the journal group to which the acquired data volume belongs and the identifier of the storage system to which the journal group belongs (step S11030).

Upon receiving a response from the information collection agent 1161, the management program 1265 stores the identifier of the received journal group and the JNL group ID 8004 of the application table 8000 therein. Also, the management program 1265 stores the identifier of the received storage system in the storage ID 8003 of the application table 8000 (step S11040).

Through the processing of the above flowchart, the application to be backed up and the information on the storage system and the journal group are associated with each other, and then set in the application table 8000.

Subsequently, a process at the time of creating the recovery point will be described.

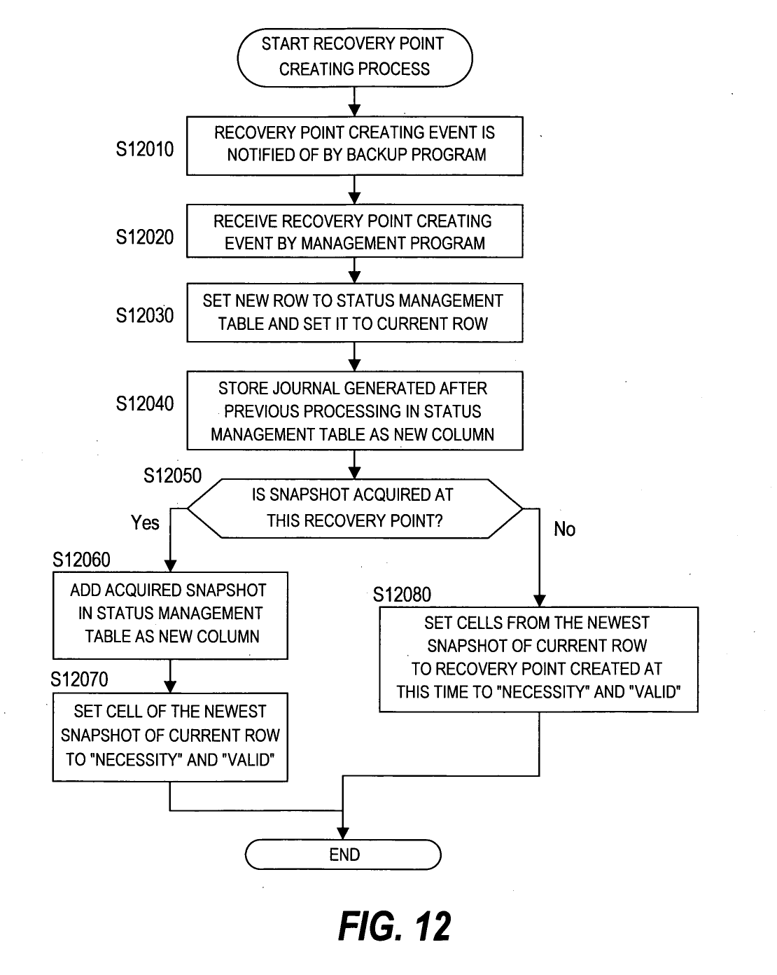

FIG. 12 is a flowchart showing a process at the time of creating the recovery point.

The backup program 1263 starts a process of creating the recovery point on the basis of a policy that is set by the administrator. The policy is generally designated with a time interval. In other words, the backup program 1263 executes the process of creating the recovery point when the designated time interval is obtained.

First, the backup program 1263 notifies the management program 1265 of the recovery point creation event at the time of executing the process of creating the recovery point. More specifically, the backup program 1263 transmits the recovery point table 7000 to the management program 1265, thereby notifying the management program 1265 of the recovery point creation event (step S12010).

Upon receiving the recovery point creation event (step S12020), the management program 1265 executes the following process.

First, the management program 1265 adds a new row to the status management table 9000 and sets the added row to a current row.

The management program 1265 stores the acquisition time 7002 of the recovery point table 7000 in the recovery point ID 9011 of the recovery point header on the added row as an initial value. Also, the management program 1265 sets “validity” in the validity flag 9012 as the initial value. Also, the respective cells on the added new row set “unnecessity” in the necessity flag 9013 as the initial value. Also, the cells set blank in the validity flag 90032 (in the status management table 9000, this is indicated by “−”) (step S12030).

Subsequently, the management program 1265 adds the journal that is created after the journal that has been previously produced through this process to the status management table 9000 as a new row with reference to the journal volume table 4000 and the snapshot table 5000. The management program 1265 sets a value of the sequence number field 4002 that is stored in the journal volume table 4000 in the Snap/JNL headers on the respective added rows as the journal ID. Also, the management program 1265 sets “validity” in the validity flag as the initial value. Also, the respective cells of the added new column set “unnecessity” in the necessity flag as the initial value. Also, the validity flag is set to blank as the initial value (step S12040).

Through the processing of the above step, the entry corresponding to the newly recorded journal is stored in the status management table 9000.

Subsequently, the management program 1265 determines whether or not the snapshot has been acquired at the recovery point on the current row with reference to the snapshot table 5000 and the recovery point table 7000 (step S12050).

In the case where it is determined that the snapshot has been acquired at the recovery point of the current row, the management program 1265 adds the acquired snapshot to the status management table 9000 as a new row. The Snap/JNL header of the new row sets a snapshot volume ID that is stored in the snapshot table 5000, and sets “validity” in the data validity flag as an initial value. In each of the cells on the added row, “unnecessity” is set in the necessity flag as an initial value, and a blank is set in the validity flag as an initial value (step S12060).

In this situation, the snapshot is acquired as determined in step S12050 at the recovery point related to the recovery point creation event which is a trigger of this process. Accordingly, data required to recover this recovery point is satisfied with only the acquired snapshot. Therefore, the management program 1265 changes the necessity flag to “necessity” and the validity flag to “validity” with respect to the cells corresponding to the newest snapshot that is added in step S12060 in the current row (step S12070). Thereafter, the processing is finished.

On the other hand, in step S12050, in the case where it is determined that the snapshot is not acquired, the management program 1265 needs, as data required to recover this recovery point, the newest snapshot and all of the journals that are acquired since that snapshot is acquired until this recovery point is acquired. Under the circumstances, the management program 1265 changes the necessity flag 9031 to “necessity” and sets the validity flag 9032 to “validity” in the cells that are within the journal corresponding from the newest snapshot to the currently created recovery point on the current row (step S12080). Thereafter, the processing is finished.

Through the processing of the above flowchart, when the recovery point is created, the information on the corresponding snapshot and journal is set in the status management table 9000. More particularly, information indicating which snapshot or journal is required (necessity flag 9031) is set with respect to the recovery point.

Subsequently, a process at the time of receiving the volume failure event will be described.

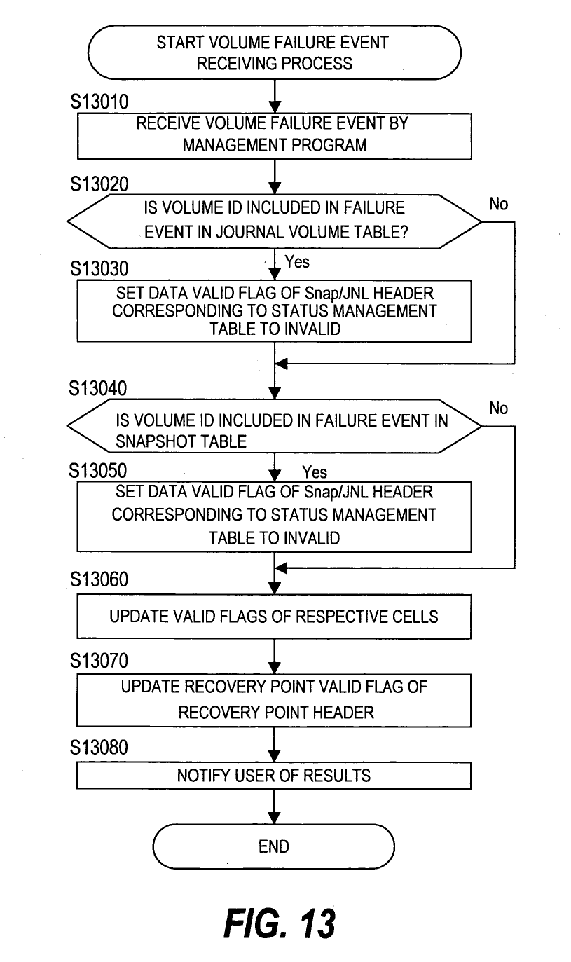

FIG. 13 is a flowchart showing a process of receiving the volume failure event.

Upon receiving the volume failure event from the failure management program 1035 of the storage system 1000 (step S13010), the management program 1265 starts a process of updating the status management table 9000.

The management program 1265 receives the volume failure event asynchronously. There is a method of receiving the event, for example, in which the failure management program 1035 of the storage system 1000 may be periodically polled from the management program 1265 to acquire the volume failure event.

Subsequently, the management program 1265 acquires the failure volume ID 2002 from the volume failure table 2000 included in the volume failure event. Then, it is determined whether the same volume ID as the failure volume ID 2002 exists in the volume ID field 4003, or not, with reference to the journal volume table 4000 (step S13020).

In the case where it is determined that the same volume ID as the failure volume ID 2002 exists, the management program 1265 sequentially refers to the respective entries 4006 of the journal volume table 4000. Then, in the case where the volume ID that is stored in the volume ID field 4003 of the referred entry 4006 is the same as the failure volume ID, the management program 1265 acquires the sequence number that is stored in the sequence number field 4002 on that row. Then, the management program 1265 refers to the status management table 9000, and if there is a Snap/JNL header having the same value as the acquired sequence number in the Snap/JNL header field 9020, the management program 1265 sets the validity flag 9022 of the Snap/JNL header to “invalidity” (step S13030).

Through the processing, the journal of the sequence number corresponding to the failure volume ID is set to “invalidity” in the status management table 9000. Thereafter, the processing is shifted to step S13040.

In step S15020, in the case where it is determined that the same volume ID as the failure volume ID does not exist, the management program 1265 shifts to step S13040 without execution of the processing of step S 13030.

In step S13040, the management program 1265 determines whether or not the same volume ID as the failure volume ID 2002 is stored in the volume ID field 5003 of the snapshot table 5000.

In the case where the same volume ID as the failure volume ID is stored in the volume ID field 5003 of the snapshot table 5000, the management program 1265 sequentially refers to the respective entries 5006 of the snapshot table. Then, in the case where the volume ID that is stored in the volume ID field 5003 of the referred entry 5006 is the same as the failure volume ID 2002, the management program 1265 acquires the snapshot volume ID that is stored in the snapshot volume ID field 5004 of the entry 5006. Subsequently, the management program 1265 refers to the status management table 9000, and when there is a Snap/JNL header having the same value as the acquired snapshot volume ID among the Snap/JNL header field 9020, the management program 1265 sets the validity flag 9022 of the Snap/JNL header to “invalidity” (step S13050).

Through the above processing, in the status management table 9000, the snapshot of the snapshot volume ID corresponding to the failure volume ID is set to “invalidity”. Thereafter, the processing is shifted to step S 13060.

In step S13040, in the case where it is determined that the same volume as the failure volume ID does not exist, the management program 1265 shifts to step S13060 without execution of the processing of step S13050.

In step S13060, the management program 1265 sequentially refers to the Snap/JNL header included in the Snap/JNL header field 9020 of the status management table 9000. Then, when the validity flag 9022 of the referred Snap/JNL header is “invalid”, the management program 1265 sequentially refers to the respective cells included in that cell. Then, in the case where the necessity flag 9031 of the referred cell is “necessity”, the management program 1265 changes the validity flag 9032 of the cell to “invalidity”. The management program 1265 executes all of the Snap/JML headers in the Snap/JNL header field 9020 (step S15060).

Subsequently, the management program 1265 updates the contents of the respective recovery point headers in the recovery point header field 9010. More specifically, the management program 1265 first sequentially refers to the recovery point headers included in the recovery point header field 9010 of the status management table 9000. Then, it is determined whether there is a cell whose validity flag 9032 is set to “invalidity”. Then, when there is a cell whose validity flag 9032 is set to “invalidity”, the management program 1265 updates the recovery point validity flag 9012 of the recovery point header to “invalidity”. The management program 1265 executes the above process with respect to all of the recovery point headers in the recovery point header field 9010 (step S13070).

In the case where, through the above process, in the status management table 9000, the snapshot of the snapshot volume ID required in order to recover the recovery point is set to “invalidity”, the recovery point is set to “invalidity”. Thereafter, the processing is shifted to step S13080.

Finally, the management program 1265 notifies the user of the contents of the updated status management table 9000 (step S13080).

Subsequently, a notification to the user will be described.

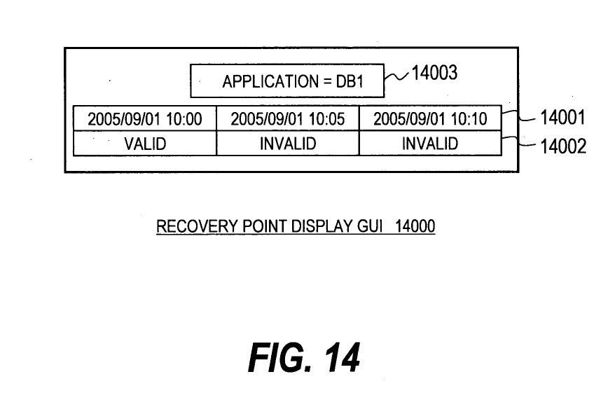

In step S13080 of the above-mentioned flowchart shown in FIG. 13, the management program 1265 of the management computer 1200 notifies the user of the management computer 1200 of the occurrence of the failure volume and the range of an influence on the application or the recovery point due to the occurrence of the failure volume. The management program 1265 notifies the user of the management computer 1200 of the above extent of the impact by the GUI that is exemplified in FIGS. 14 to 16.

FIG. 14 is an explanatory diagram showing an example of the GUI that is notified the user of.

A recovery point display GUI 14000 is a GUI for displaying a list of the recovery points and whether the recovery points are valid or invalid on the display device 1220 by the management program 1265.

The recovery point display GUI 14000 includes a recovery point field 14001, a validity field 14002, and an application name 14003 therein.

The recovery point field 14001 displays a recovery point ID that is an identifier of the recovery point.

The validity field 14002 displays whether the recovery point indicated by the recovery point ID is valid or invalid.

The application name 14003 displays an application ID that is an identifier of the application to be backed up. The management program 1265 refers to the application table 8000 by using a value of the JNL group ID field 9001 in the status management table 9000 to acquire the application ID 8001, and displays the acquired application ID 8001 in the application name 14003.

In an example of FIG. 14, the validity or invalidity is indicated by character strings, but the validity or invalidity may be indicated by graphics such as icons.

Also, in the case where the validity field 14002 is “validity”, the administrator clicks the corresponding portion by a mouse provided in the input device 1240 to start the backup program 1263, thereby making it possible to execute the restoring function of the backup program 1263.

Also, in the case where the validity field 14002 is “invalidity”, the administrator clicks the corresponding portion by a mouse or the like provided in the input device 1240 to execute the function of the recovery manager 1162 of the host computer 1100. This makes it possible to display a relationship of the application, the data volume, and the volume in which the failure occurs by the management program 1265 from the information included in the system configuration definition file 1171 that is stored in the local disk 1170 of the host computer 1100.

The GUI shown in FIG. 14 is a display for one application. On the contrary, plural applications may be displayed at the same time.

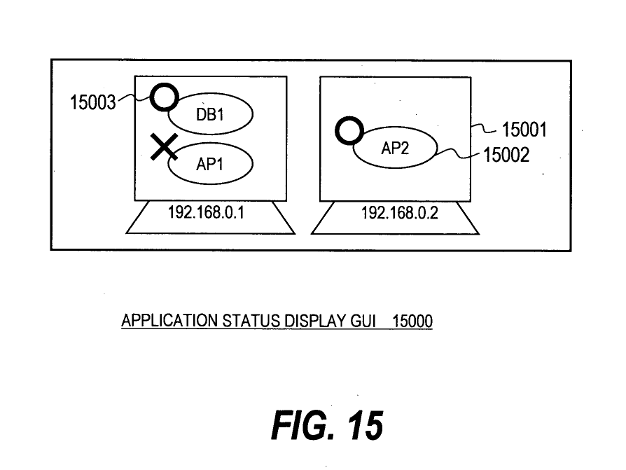

FIG. 15 is an explanatory diagram showing another example of the GUI that is notified the user of.

FIG. 15 shows a display example of an application status display GUI 15000 in the case where three applications are operating in the computer system.

The application status display GUI 15000 includes a host icon 15001, an application icon 15002, and a status icon 15003.

The host icon 15001 schematically displays the host computer 1100 that executes the application together with the host ID. The host ID uses a host name, an IP address, or the like.

The application icon 15002 schematically displays the application that is executed by the host computer 1100. The application icon 15002 is displayed together with the application ID within the host icon which displays the host computer that executes the application.

The administrator clicks the application icon 15003 by a mouse disposed in the input device 1240, thereby making it possible to display the details of the data volume and the journal volume which are used by the application.

The status icon 15003 schematically displays the status of the application. The status icon 15003 is displayed in the vicinity of the application icon 15002, and displays a graphic indicative of the status of the application. The status displays an icon indicative of the validity or invalidity. For example, in the case where all of the recovery points of the application is valid, an icon of “O”, indicative of validity is displayed. Also, when there is an invalid recovery point in a part of the application, an icon of “X”, indicative of invalidity is displayed. In the case of validity, it is possible that icon is not displayed, and only the icon indicative of invalidity is displayed.

In the case of operating the backup due to journaling by using plural applications by means of the application status display GUI 15000 of FIG. 15, the user can know in which application a failure occurs while referring to the application status display GUI 115000 at one view.

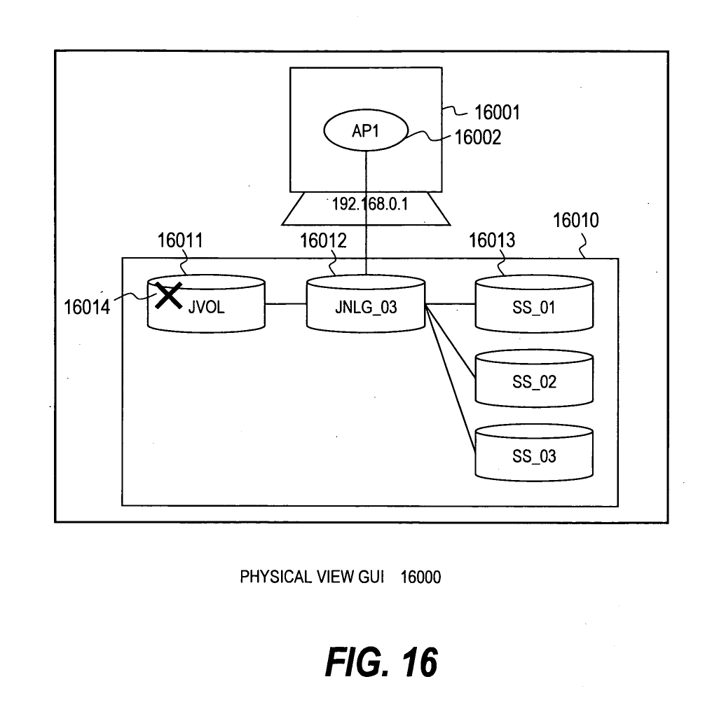

FIG. 16 shows a physical view GUI 16000 that is displayed when the administrator clicks the application icon 15002 that is displayed on the application status display GUI 15000 by a mouse or the like disposed in the input device 1240.

The physical view GUI 16000 includes a host icon 16001, an application icon 16002, a storage system icon 16010, a journal volume icon 16001, a journal group icon 16012, a snapshot volume icon 16013, and a status icon 16014.

The host icon 16001 and the application icon 16002 display the host ID of the host computer 1100 that executes the application and the application ID that is executed by the host computer as with the host icon 15001 and the application icon 15002 which are displayed on the application status display GUI 15000.

The storage system icon 16010 displays the storage system 1000 that is used for backup operation due to journaling by the application. In FIG. 16, only one storage system is displayed, but plural storage systems may be displayed.

The journal volume icon 16011 displays the journal volume 1013 of the storage system 1000 together with the volume ID that is an identifier of the journal volume 1013. The journal group icon 16012 displays the journal group 1014 of the storage system 1000 together with the JNL group ID that is an identifier of the journal group 1014. The snapshot volume icon 16013 displays the snapshot volume 1012 of the storage system 1000 together with the snapshot volume ID of the snapshot volume 1012.

The status icon 16014 is an icon indicating that a failure occurs, and displayed on a portion where the failure occurs.

The management program 1265 may provide a function of switching display between the physical view GUI 16000 and the recovery point display GUI 14000. The user know where the failure has occurred and which recovery point has been invalid by switching display between the physical view GUI 16000 and the recovery point display GUI 14000. The physical view GUI 16000 and the recovery point display GUI 14000 may be displayed on the same display screen at the same time.

As described above, the management program 1265 notifies the user of the failure occurrence by GUI. As a result, the user can know in which volume used by which program the failure occurs at one view.

In FIGS. 14 to 16, the notification to the user is conducted by GUI, and this invention is not limited to this configuration. For example, the management program 1265 may notify the user of the invalidated recovery point by means of the SNMP trap or the like. Also, the management program 1265 may notify the user of the occurrence of volume failure and suggest the user to refer to display using GUI.

As described above, according to the first embodiment of this invention, in the case where a failure occurs in the volume that configures the snapshot or the journal, the recovery point that has been invalidated by the failure can be automatically detected, thereby making it possible to continue the operation at other recovery points.

### Second Embodiment

In the above-mentioned computer system according to the first embodiment, the management program 1265 of the management computer 1200 stores all of the information on the journals that have occurred after creating recovery points at a previous time in the row of the status management table 9000 every time the management program 1265 creates the recovery point. In general, since the journal is created every time the journal is written from the host computer 1100, the number of entries of the status management table 9000 becomes very larger as a time elapses. For that reason, the management computer 1200 must manage the enormous quantity of data. Under the circumstances, in order to reduce the quantity of data that is managed by the management computer 1200, there is applied the following method.

The same operational structures as those in the first embodiment are denoted by identical references, and their description will be omitted.

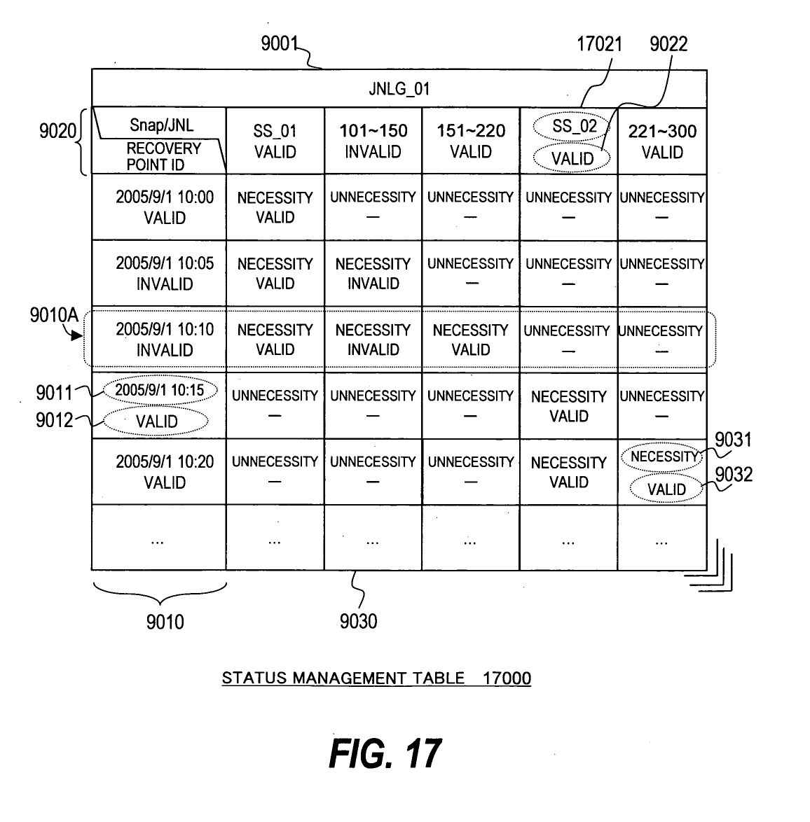

FIG. 17 is an explanatory diagram showing an example of a status management table 17000 included in the backup management information 1264 according to the second embodiment of this invention.

In the status management table 17000, the configuration of the respective Snap/JNL headers of he Snap/JNL header field 9020 are different from those in the first embodiment. In other words, an identifier 17021 stores the snapshot ID or plural continuous journal identifiers therein. The plural continuous journals are a journal group that groups the journals that have been acquired between a certain recovery point and the subsequent recovery point as one group.

Now, the operation of the computer system according to the second embodiment will be described.

The management program 1265 executes a recovery point creating process that creates the status management table 17000 shown in FIG. 17.

The above process is substantially the same as that in the flowchart shown in FIG. 12. In step S12040 of FIG. 12, the management program 1265 does not create rows in each of the snapshots, but puts all of the snapshots leading from the previous recovery point to the recovery point that has been acquired at this time into one group. More specifically, the management program 1265 stores an identifier 17021 with the sequence number of the journal that has been acquired immediately after a previous recovery point has been acquired as a start point and the sequence number of a recovery point that has been acquired at this time as an end point.

For example, in the example of FIG. 17, identifiers 101 to 150 are put into one group, identifiers 151 to 220 are put into one group, and identifiers 221 to 300 are put into one group.

For example, the management program 1265 sets the identifier 17021 as “101 to 150” in the case where the recovery point is acquired in the journal whose sequence number is 150 after the snapshot SS_01 has been acquired in the sequence number 100. The management program 1265 sets an initial value to “valid” in the validity flag 9022 of the added Snap/JNL header field 9020. Also, the management program 1265 sets an initial value of the necessity flag 9031 to “unnecessity” and sets an initial value of the validity flag 9032 to blank in the respective cells of the respective added rows.

Other processes are the same as those in the flowchart shown in FIG. 12.

Also, the management program 1265 executes the volume failure event receiving process. This process is substantially the same as that described with reference to FIG. 13, but the following process is executed in step S13030 of FIG. 13.

Since it is found that a failure occurs in any volume that configures the journal volume, the management program 1265 acquires the sequence number of the journal which is stored in the volume in which the failure occurs from the journal volume table 4000. Then, the management program 1265 retrieves the Snap/JNL header in which the acquired sequence number is included from the Snap/JNL header field 9020 of the status management table 17000. Then, the management program 1265 sets the data validity flag of the Snap/JNL header to “invalidity”.

For example, in the case where a failure occurs in the journal of the sequence number “125”, in FIG. 17, the management program 1265 sets the validity flag 9022 of a cell that is “101 to 150” including the sequence number “125” to invalidity. The management program 1265 executes the above process with respect to the respective rows of the journal volume table.

Other processes are the same as those in the flowchart of FIG. 13.

As described above, according to the second embodiment of this invention, it is possible to reduce the management data that must be managed by the management computer in addition to the advantages obtained in the above-described first embodiment.

### Third Embodiment

Now, a third embodiment will be described.

In the above-described first and second embodiments, there is one method in which a certain recovery point is recovered. However, in fact, the method of recovering one recovery point is not limited to one method.

For example, there are following method.

First, there is a method using a before journal.

As in the technique disclosed in the specification of US 2005/0015416, overwrite data is saved to a different area by application of the journal. Then, in the case of canceling the application of the journal, the saved data is rewritten to an original position with respect to the snapshot to which the journal has been applied. This makes it possible to restore the data image that is before the application of the journal in a short time. This journal is called “after journal”, and the saved data is called “before journal”. The above-mentioned first and second embodiments are processes using the after journal.

In the case of managing the after journal and the before journal at the same time, there can be used two methods in order to recover a certain recovery point. One method is a method in which, with an initial snapshot when a time axis is dated back to a past direction from the recovery point as a base, the after journal is applied to the snapshot to conduct recovery. In the other method, with an initial snapshot when the time axis is dated forward to a future direction from the recovery point as a base, the before journal is applied to that method to conduct recovery.

As described above, when there are employed two kinds of recovering methods using the after journal and the before journal, the recovery point is valid so far as both of the after journal and the before journal are not invalid. Accordingly, even if a failure occurs in the disk device, the recovery points that are invalidated are reduced, and the fault tolerance to the backup operation becomes enhanced.

Also, there is a method that conducts the recovery at the time point of the snapshot without using the snapshot apart from the use of the before journal. As usual, in order to conduct the recovery at a time point where the snapshot has been acquired, only the snapshot may be used. However, in the case where a failure occurs in the volume that stores the snapshot, recovery cannot be conducted. For that reason, the journals to the snapshot in which the failure occurs are applied to the snapshot immediately before the snapshot in which the failure occurs, thereby making it possible to recover the data at the same time as that of the snapshot in which the failure occurs.

A description will be given below of a method of managing the validity of the recovery point in the case where there exist plural methods for recovering the data at a certain recovery point as mentioned above.

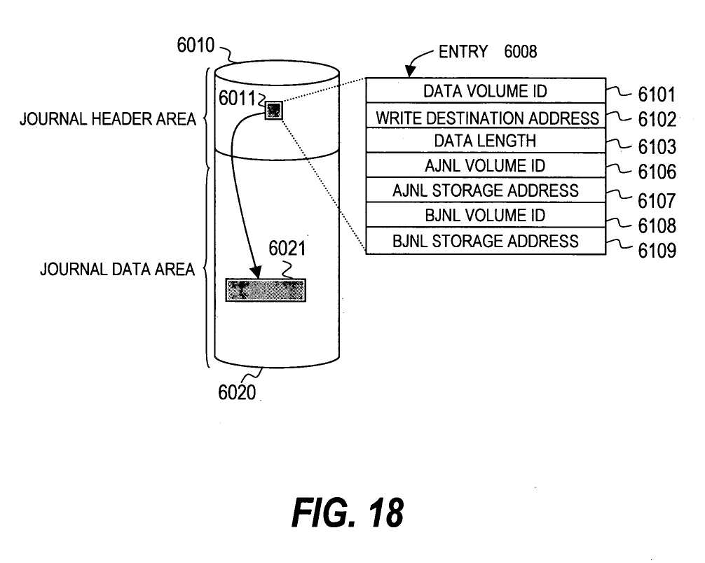

FIG. 18 is an explanatory diagram showing the structure of a journal volume 1013 according to the third embodiment.

As described above, the journal volume 1013 is logically divided into the journal header area 6010 and the journal data area 6020.

In this embodiment, the entry 6008 of the journal header further includes a BJNL volume ID 6108 and a BJNL storage address 6109.

The BJNL volume ID 6108 stores the identifier of the volume that stores the journal data of the before journal therein. The BJNL volume ID 6109 stores an address at which the journal data of the before journal is stored therein.

Those values are set by the storage microprogram 1028 at the time of creating the before journal. Also, in the case of opening the journal data of the before journal, the storage microprogram 1028 sets “NULL” in the BJNL volume ID 6108, and “NULL” in the BJNL storage address 6109, respectively.

Also, in the case where all of the AJNL volume ID 6106, the AJNL storage address 6107, the BJNL volume ID 6108, and the BJNL storage address 6109 are NULL, the storage microprogram 1028 opens the journal header.

When writing is conducted from the host computer 1100, the storage microprogram 1028 creates the journal header only at the time of creating the after journal. In other words, at the time of creating the before journal, the storage microprogram 1028 sets the identifier of the volume in which the journal data 6021 of the before journal is stored in the BJNL volume ID 6108, and the stored address in the BJNL storage address 6109, respectively. Likewise, in the case of recreating the after journal that is opened once, the storage microprogram 1028 sets the identifier of the volume in which the journal data 6021 of the after journal is stored in the AJNL volume ID 6106, and the stored address in the AJNL storage address 6107, respectively.

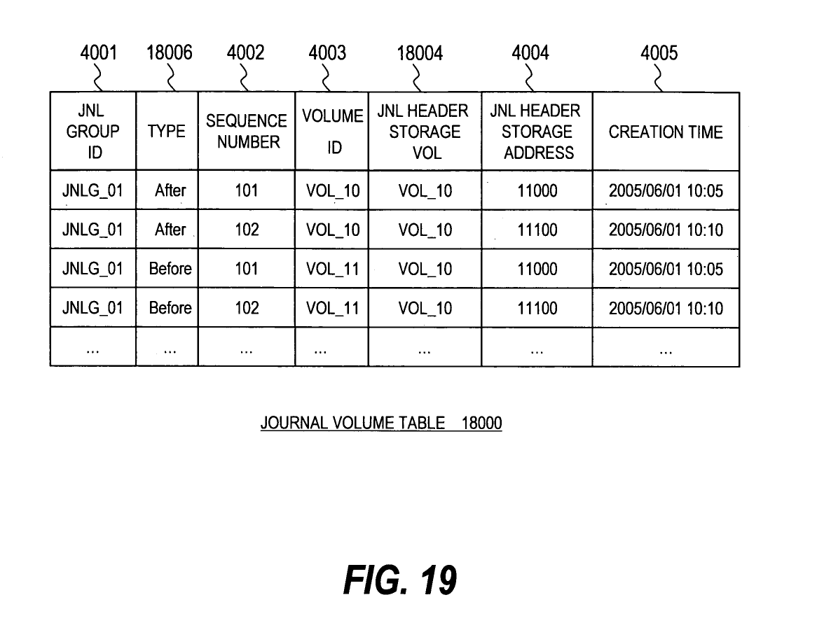

FIG. 19 is an explanatory diagram showing an example of a journal volume table 18000 included in the management table 1029.

The storage microprogram 1028 creates the after journal or before journal and stores the journal in the journal volume 1012 of the journal volume 1013 every time writing is conducted with respect to the journal group 1014 from the host computer 1100. In this situation, the storage microprogram 1028 creates the entry 4006 corresponding to the created journal data, and adds the entry 4006 to the journal volume table 18000.

A journal volume table 18000 is so configured as to include a type field 18006 indicating whether the journal is the after journal or the before journal, and a JNL header storage VOL field 18004 that stores the identifier of the volume in which the journal header is stored therein in addition to the above-mentioned journal volume table 4000 shown in FIG. 4.

The sequence number field 4002 holds the sequence number. The storage microprogram 1028 sets the sequence number in the sequence counter 3003 of the journal group table 3000 at the time of creating the after journal with respect to writing from the host computer 1100. Then, the storage microprogram 1028 acquires the sequence number and sets the sequence number in the sequence number field 4002.

Alternatively, the backup program 1263 acquires the after journal that is the base of the before journal when instructing the creation of the before journal, acquires the sequence number of the acquired after journal, and sets the sequence number in the sequence number field 4002.

At the time of writing the journal in the journal volume 1013, the storage microprogram 1028 acquires the journal header, the volume ID in which the journal is written, and the JNL header storage address, and sets those acquired values in the volume ID field 4003, the JNL header storage VOL field 18004, and the JNL header storage address field 4004, respectively.

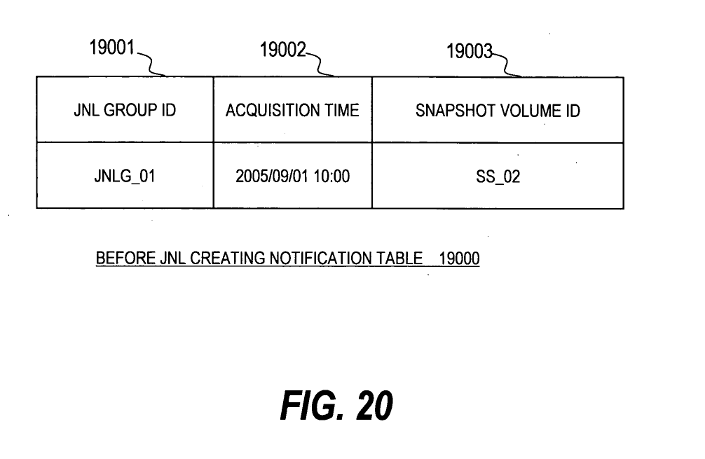

FIG. 20 shows a configuration of a before JNL creation notification table 19000 in this embodiment.

The before journal creation notification table 19000 includes a JNL group ID field 19001, an acquisition time field 19002, and a snapshot volume ID field 19003.

The backup program 1263 creates the before journal at an arbitrary timing. In this situation, the backup program 1263 creates the before journal leading from a certain snapshot volume to a subsequent snapshot volume in a time axial direction.

In this situation, the backup program 1263 sets the identifier of the JNL group from which the before journal is to be acquired in the JNL group ID field 19001 with respect to the created before journal, acquires a time at the time point from the timer 1024, and sets the time in the acquisition time field 19002. Then, the backup program 1263 creates a unique identifier with respect to the acquired snapshot volume, and sets the unique identifier in the snapshot volume ID field 19003.

Upon creating the before JNL creation notification table 19000, the backup program 1263 notifies the management program 1265 of the created before JNL creation notification table 19000 as the before journal creation event. This notification uses the SNMP trap as described above, but may use other notifying methods.

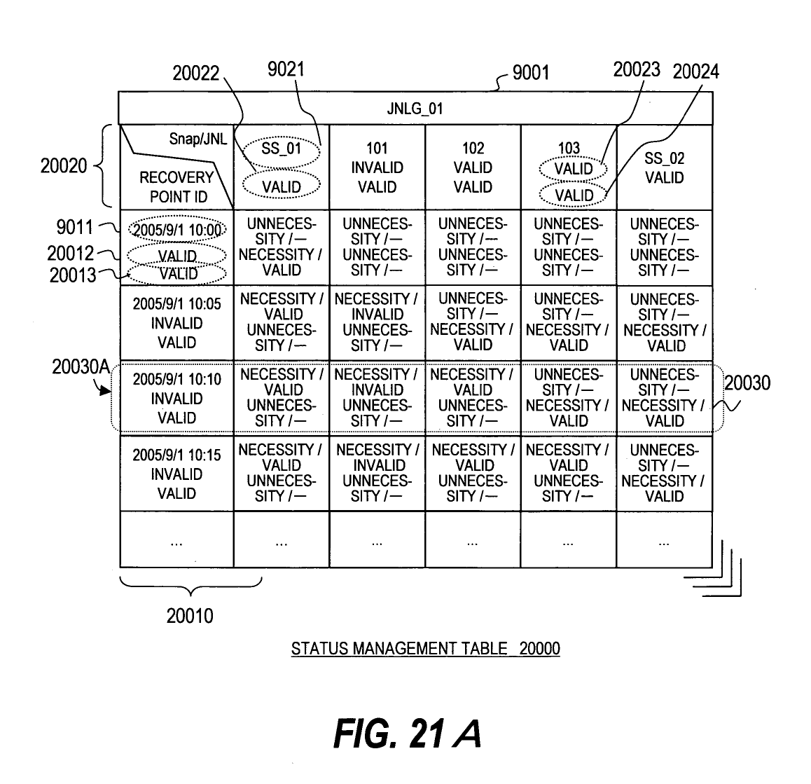

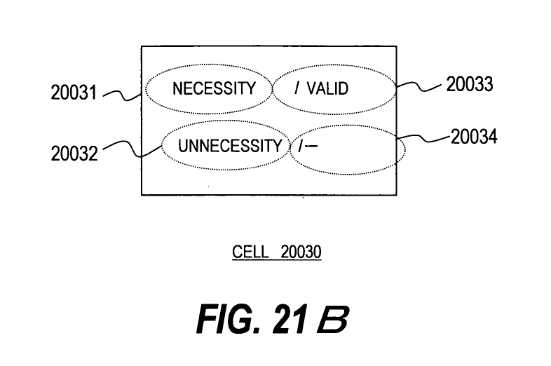

FIGS. 21A and 21B are explanatory diagrams showing an example of a status management table 20000 included in the backup management information 1264.

The status management table 20000 has the same configuration as that of the above-mentioned status management table 9000. The status management table 20000 sets the necessity flag and the validity flag in the after journal and the before journal, respectively.

The recovery point header field 20010 stores the recovery point ID and its status therein. The Snap/JNL header field 20020 stores the identifier of the snapshot, the identifier of the journal, and its status which are required to recover the respective recovery points therein.

The respective recovery point headers of the recovery point header field 20010 includes a recovery point ID 9011, a recovery point validity flag (after) 20012, and a recovery point validity flag (before) 20013.

The recovery points provide the validity flags in the recovering method due to the after journal and the recovering method due to the before journal, respectively.

Each of the Snap/JNL headers that configure the Snap/JNL header field 20020 includes an identifier 9021 and a validity flag.

In the case where the cell of the validity flag indicates the snapshot, the validity flag stores the snapshot validity flag 20022. Also, in the case where the cell indicates the journal, two of the after JNL validity flag 20023 and the before JNL validity flag 20024 are stored therein.

FIG. 21B is an explanatory diagram showing an example of the configuration of the respective cells that configure the table.

A cell 20030 includes a necessity flag (after) 20031, a validity flag (after) 20033, a necessity flag (before) 20032, and a validity flag (before) 20034.

As described above, in order to recover the recovery points on the respective rows, there are the method using the after journal, and the method using the before journal.

For that reason, the cell 20030 includes the necessity flag 20031 and the validity flag 20033 for the after journal, and the necessity flags 20032 and 20034 for the before journal.

Referring to FIG. 21A, it is found that on a row 20030A indicative of the recovery point “2005/9/1 10:10”, the journals and the snapshots which are required in order to recover the recovery point “2005/9/1 10:10” by the after journal are three of “SS_01”, “101”, and “102” where the necessity flag is set to “necessity”. Also, it is found that the journal “101” is invalid. On the other hand, the journals and the snapshots which are required in order to recover the recovery point by the before journal are two of “SS_02” and “103”, and it is found that all of them are valid.

Accordingly, at the recovery point “2005/9/1 10:10”, the recovery in the after journal is “invalid”, and the recovery in the before journal is “valid”.

Subsequently, the operation of a computer system according to the third embodiment will be described.

The management program 1265 executes three processes, i.e., setting of the information at the time of setting the system, updating of the status management table at the time of receiving the event from the backup program, and updating of the status management table at the time of receiving the volume failure event, as described above.

Setting of the information at the time of setting the system is the same as the flowchart shown in FIG. 11 according to the above-mentioned first embodiment.

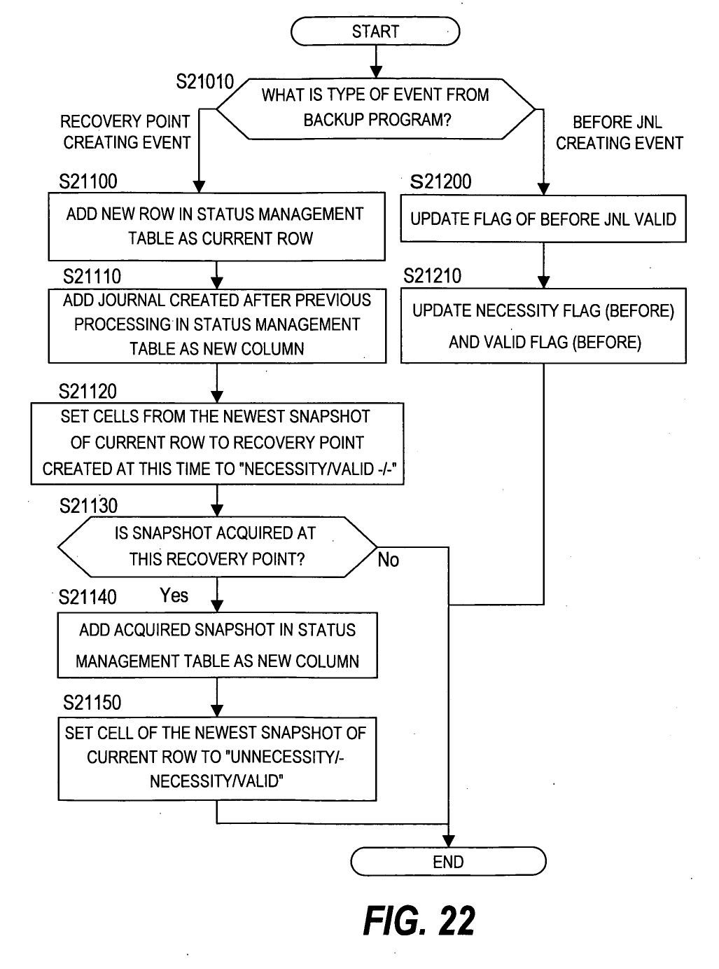

FIG. 22 is a flowchart showing a process at the time of creating the recovery point according to the third embodiment.

The backup program 1263 issues the recovery point creation event with respect to the management program 1265 at a timing of creating the recovery point. Also, the backup program 1263 issues the before JNL creation notification event with respect to the management program 1265 at a timing of creating the snapshots up to a certain snapshot.

The management program 1265 starts the processing of this flowchart at the time of receiving the recovery point creation event or the before JNL creation notification event which has been issued by the backup program 1263.

First, the management program 1206 determines the type of the received event is the recovery point creation event, or the before journal creation notification event (step S21010).

First, a process in the case of the recovery point creation event will be described.

In step S21100, the management program 1265 adds a new row to the status management table 9000, and sets the added row to the current row (step S21110).

In this situation, the management program 1265 stores the acquisition time 7002 of the recovery point table 7000 in the recovery point ID of the recovery point header on the added row as an initial value. Also, the management program 1265 sets “validity” in the validity flag 20012 as the initial value, and sets blank in the validity flag 20014 as the initial value. Also, the respective cells on the added new row set “unnecessity” in the necessity flag (after) 20031 as the initial value. Also, the cells set blank in the validity flag (after) 20033, and sets blank in the necessity flag (before) 20032. Also, the cells set blank in the validity flag (before) 20034.

Subsequently, the management program 1265 adds the journal that is created after the journal that has been previously produced through this process to the status management table 20000 as a new row with reference to the journal volume table 18000 and the snapshot table 5000. The management program 1265 sets a value of the sequence number field 4002 that is stored in the journal volume table 18000 in the Snap/JNL headers on the respective added rows as the journal ID. Also, the management program 1265 sets “validity” and “−” in the validity flag as the initial values. Also, the respective cells of the added new row set “unnecessity” in the necessity flag (after) 20031 as the initial value. Also, the validity flag (after) 20033 is set to blank. The necessity flag (before) 20032 is set to blank. Also, the validity flag (before) 20034 is set to blank (step S21110).

Subsequently, the flag on the current row is set. The “necessity” is set in the necessity flag (after) of the cells leading from the newest snapshot to the recovery point that is created at this time, and “validity” is set in the validity flag (after) (step S21120).

Subsequently, the management program 1265 determines whether or not the snapshot has been acquired at the recovery point on the current row with reference to the snapshot table 5000 and the recovery point table 7000 (step 21130).

When the snapshot is not acquired, the processing is finished.

In the case where it is determined that the snapshot has been acquired at the recovery point of the current row, the management program 1265 adds the acquired snapshot to the status management table 20000 as the new row (step S21140).

Then, the management program 1265 sets “necessity” in the necessity flag (before) 20032 of the cell of the added snapshot in step S21140, and sets “validity” in the validity flag (before) 20034. The snapshot can be recovered even if the before journal is not employed, but the management program 1265 sets the field of before in order to express the validity of the recovery of only the snapshot (step S21150).

Then, a process in the case of the before JNL creation notification event will be described.

The management program 1265 acquires the Snap/JNL header indicative of the journal which exists between the Snap/JNL header of the same identifier as that of the snapshot volume ID included in the received event, and the Snap/JNL header having the snapshot volume ID that has been acquired before by one that Snap/JNL header as the identifier in the Snap/JNL header field. Then, the management program 1265 sets all of the before JNL validity flag of the Snap/JNL header indicative of the acquired journal to “validity” (step S21200).

Subsequently, the management program 1265 sequentially refers to the necessity flag (after) 20012 of the respective recovery point header fields 20010. Then, in the case where there is a recovery point header whose necessity flag (after) 20012 is valid, and the subsequent recovery point header is invalid, the management program 1265 sets the necessity flag (before) 20032 of the cell included in the subsequent snapshot volume to “necessity”, and sets the validity flag (before) 20034 to the same value as that of the validity flag of the before JNL, from the cell included in the subsequent row (step S21210).

Subsequently, a volume failure event receiving process will be described.

Upon receiving the volume failure event from the failure management program 1035 within the storage system 1000, the management program 1265 updates the status management table 20000. This process is substantially the same as that of the above flowchart shown in FIG. 13, but is different therefrom in the following process.

In step S13030, in the case where it is determined that there exists the same volume ID as that of the failure volume ID 2002, the management program 1265 sequentially refers to the respective entries 4006 of the journal volume table 18000. Then, in the case where the volume ID that is stored in the volume ID field 4003 of the referred entry 4006 is the same as the failure volume ID, the management program 1265 acquires a value that is stored in the type field 18006 and the sequence number 4002 on that row.

Then, the management program 1265 sets the after JNL validity flag 20023 or the before JNL validity flag 20024 of the Snap/JNL header to “invalidity” according to the value of the acquired type field when there is a Snap/JNL header having the same value as the acquired sequence number in the Snap/JNL header field 20020 with reference to the status management table 9000.

Through the above process, in the status management table 20000, the snapshot of the snapshot volume ID corresponding to the failure volume ID is set to “invalidity”.

Then, in step S13060, the management program 1265 sequentially refers to the Snap/JNL header included in the Snap/JNL header field 9020 of the status management table 20000. Then, when the validity flag 20022 of the referred Snap/JNL header is “invalidity”, the management program 1265 sequentially refers to the respective cells included in that row. Then, when the necessity flag (after) 20031 of the referred cell is “necessity”, the management program 1265 sets the validity flag (after) 20033 of the cell to “invalidity”. Also, when the necessity flag (before) 20032 of the referred cell is “necessity”, the management program 1265 changes the validity flag (before) 20034 of the cell to “invalidity”. The management program 1265 executes the above process with respect to all of the Snap/JNL headers of the Snap/JNL header field 20020.

Then, in step S13070, first, the management program 1265 sequentially refers to the recovery point header included in the recovery point header field 20010 of the status management table 20000. Then, the management program 1265 determines whether or not there is a cell whose validity flag (after) 20032 is set to “invalidity” among the cells corresponding to the referred recovery header. Then, when there is a cell whose validity flag (after) 20032 is set to “invalidity”, the management program 1265 updates the recovery point validity flag (after) 20012 of the recovery point header to “invalidity”.

In addition, the management program 1265 determines whether or not there is a cell whose validity flag (before) 20034 is set to “invalidity” among the cells corresponding to the referred recovery point header. Then, when there is a cell whose validity flag (before) 20034 is set to “invalidity”, the management program 1265 updates the recovery point validity flag (before) 20013 of the recovery point header to “invalidity”. The management program 1265 executes the above process with respect to all of the recovery point headers of the recovery point header field 20010.

Then, in step S13080, the management program 1265 notifies the user of the updated status management table 20000. In this situation, the management program 1265 determines, if either one of the recovery point validity flag (after) 20012 and the recovery point validity flag (before) 20013 is “validity” with reference to the respective cells of the recovery point header field 20010, that recovery point is valid.

The GUI shown in FIGS. 14 to 16 is used as the notifying means as in the first embodiment.

As described above, in the third embodiment of this invention, in the case where there are plural means for recovering the recovery point, even if some of those means are lost due to the occurrence of the failure, when at least one valid means remains, its recovery point is regarded as the validity, and the operation can be continued.

While the present invention has been described in detail and pictorially in the accompanying drawings, the present invention is not limited to such detail but covers various obvious modifications and equivalent arrangements, which fall within the purview of the appended claims.

What is claimed is:

1. A data managing method that is executed by a computer system comprising: a storage system having a disk drive that stores data therein, and a controller that controls read/write of the data from/to the disk drive; a host computer that is connected to the storage system via a network and requests read/write of data which is to be stored in the disk drive; and a management computer that is connected to one of the storage system and the host computer, and manages the host computer and the storage system, wherein the disk drive includes: a data volume that stores data read/written by the host computer therein; a journal volume that stores journal data which is a differential of data written by the host computer therein every time writing is requested; and a snapshot volume that supplies a snapshot which is a restored data at a past given time of the data volume, the method comprising:
a first step of setting a recovery point indicative of the given time;
a second step of creating an information of correspondence between the snapshot and the journal data which is required to restore data at the set recovery point time;
a third step of detecting the occurrence of failure of the disk drive; and
a fourth step of detecting the recovery point at which data cannot be restored due to the failure of the disk drive.

2. The data management method according to claim 1, wherein the fourth step further comprises a step of notifying a user of the recovery point at which data cannot be restored.

3. The data managing method according to claim 1,
wherein the host computer executes a plurality of applications that request read/write of data which is to be stored in the disk drive, and the applications use different volumes, journal volumes, and snapshot volumes, respectively, and
wherein the fourth step comprises a step of specifying the application by using the recovery point at which data cannot be restored, and a step of notifying a user of a recovery point at which data cannot be restored and an application related to the recovery point in association.

4. The data managing method according to claim 1, wherein the fourth step comprises steps of judging, in a case where the failure occurs in at least one of the journal volume and the snapshot volume due to the failure of the disk drive, whether or not the journal data that is stored in the journal volume in which a failure occurs or the snapshot that is stored in the snapshot volume in which a failure occurs is included in the created corresponding information, and detecting that the recovery point related to the information of correspondence cannot restore data

5. The data managing method according to claim 1, wherein the second step creates the information of correspondence between the journal data and the snapshot which is required to restore data at a given recovery point time, with the journal data that has been stored after the recovery point time immediately before the given recovery point time and before the recovery point time as one group.

6. A management computer, comprising:
a storage system having a disk device that stores data therein;
a host computer that requests read/write of data that is to be stored in the disk drive;
an interface that is connected to the storage system and the host computer via a network;
a processor that is coupled to the interface;
a memory that stores program and information therein; and
a display device that displays information for a user,
wherein the disk drive includes: a data volume that stores data read/written by the host computer therein; a journal volume that stores journal data which is a differential of data written by the host computer therein every time writing is requested; and a snapshot volume that supplies a snapshot which is a restored data at a past given time of the data volume, and
wherein the processor:
requires setting of a recovery point indicative of the given time of the storage system;
requires information on the snapshot and the journal data which are required to restore data at the set recovery point time of the storage system;
stores an information of correspondence between the snapshot and the journal data which are retrieved as a result of the requests in the memory;
requires retrieving the storage system for the journal volume or the snapshot volume in which a failure occurs when receiving a notification that the failure occurs in the disk drive from the storage system; and
detects, when the journal volume or the snapshot volume which are retrieved as a result of the request is included in the information of correspondence, the recovery point related to the information of correspondence cannot restore data.

7. The management computer according to claim 6, wherein the processor displays the recovery point at which data cannot be restored on the display device to notify a user of the recovery point at which data cannot be restored.

8. The management computer according to claim 6,
wherein the host computer executes a plurality of applications that requires read/write of data to be stored in the disk drive, and the applications use different data volumes, journal volumes, and snapshot volumes, respectively, and
wherein the processor requires retrieving the host computer for the applications that use the recovery points at which data cannot be restored, and displays the recovery points at which data cannot be restored and the applications related to the recovery points in association on the display device as a result of the request to notify the user of the recovery points at which data cannot be restored and the applications related to the recovery points.

9. The management computer according to claim 6, wherein the processor requires retrieving the storage system for the journal volume in which the failure occurs at the time of receiving a notification that the failure occurs in the disk drive from the storage system, and refers to a result of the request and the correspondence to detect that the recovery points related to the information of correspondence at which data cannot be restored when the journal data that is stored in the journal volume in which the failure occurs or the snapshot that is stored in the snapshot volume in which the failure occurs is included in the information of correspondence.

10. The management computer according to claim 6, wherein the processor creates the information of correspondence at the time of storing the correspondence between the snapshot and the journal data which are retrieved as a result of the request, with the journal data that has been stored after the recovery point time immediately before the recovery point time and before the recovery point time as one group.

11. A computer system, comprising:
a storage system comprising: a controller including a disk interface that is coupled to a disk drive that stores data; a first interface that is coupled to a host computer and a management computer; a first processor that controls read/write of the data in the disk drive; and a first memory that stores program and information therein; and the disk device;
a host computer comprising: a second interface that is connected to the storage system and the management computer via a network; a second processor that requires read/write of data that is to be stored in the disk drive; and a second memory that stores program and information therein; and
a management computer including: a third interface that is connected to at least one of the storage system and the host computer via a network; a third processor that is coupled to the interface; a third memory that stores program and information therein; and a display device that displays information for a user,
wherein the disk drive including: a data volume that stores data read/written by the host computer therein; a journal volume that stores journal data which is a differential of data written by the host computer therein every time writing is requested; and a snapshot volume that supplies a snapshot which is a restored data at a past given time of the data volume,
wherein the third processor requires setting of the recovery point indicative of the given time of the storage system, requires of information on the snapshot and the journal data which are required to restore data at the set recovery point time of the storage system, and stores an information of correspondence between the snapshot and the journal data which are required as a result of the requests in the third memory,
wherein the first process detects the occurrence of the failure in the disk drive, and notifies the management computer of the detected failure, and
wherein the third processor requires retrieving the storage system for the journal volume and the snapshot volume in which the failure occurs at the time of receiving a notification that the failure occurs in the disk drive from the storage system, and detects that the recovery point related to the correspondence cannot restore data when the journal volume and the snapshot volume which are retrieved as a result of the request are included in the information of correspondence.

12. The computer system according to claim 11, wherein the third processor displays the recovery point at which data cannot be restored to notify a user of the recovery point at which data cannot be restored.

13. The computer system according to claim 11,
wherein the second processor executes a plurality of applications that requires read/write of data to be stored in the disk drive, and the applications use different data volumes, journal volumes, and snapshot volumes, respectively, and
wherein the third processor requires retrieving the host computer for the applications that use the recovery points at which data cannot be restored, and displays the recovery points at which data cannot be restored and the applications related to the recovery points in association on the display device as a result of the request to notify the user of the recovery points at which data cannot be restored and the applications related to the recovery points.

14. The computer system according to claim 11, wherein the third processor requires retrieving the storage system for one of the journal volume and the snapshot volume in which the failure occurs at the time of receiving a notification that the failure occurs in the disk drive from the storage system, and refers to a result of the request and the correspondence to detect that the recovery points related to the information of correspondence at which data cannot be restored when the journal data that is stored in the journal volume in which the failure occurs or the snapshot that is stored in the snapshot volume in which the failure occurs is included in the information of correspondence information.

15. The computer system according to claim 11, wherein the third processor creates the information of correspondence at the time of storing the correspondence between the snapshot and the journal data which are retrieved as a result of the request, with the journal data that has been stored after the recovery point time immediately before the recovery point time and before the recovery point time as one group.
